(19) United States
(12) Patent Application Publication
(10) Pub. No.: US 2026/0362880 A1
(43) Pub. Date: Nov. 12, 2026

(54) Light-Emitting Substrate and Display Apparatus

(71) Applicants: BOE MILED Technology Co., Ltd., Beijing (CN); BOE TECHNOLOGY GROUP CO., LTD., Chaoyang District, Beijing (CN); BEIJING BOE TECHNOLOGY DEVELOPMENT CO., LTD., Beijing (CN)

(72) Inventors: Sha Feng, Beijing (CN); Jing Wang, Beijing (CN); Lili Wang, Beijing (CN); Chao Liu, Beijing (CN); Mingming Jia, Beijing (CN); Huaimin Wang, Beijing (CN); Shanshan Feng, Beijing (CN); Mengqing Liu, Beijing (CN); Jingping Zhao, Beijing (CN); Qi Qi, Beijing (CN)

(21) Appl. No.: 19/126,384

(22) PCT Filed: Jul. 12, 2024
(86) PCT No.: PCT/CN2024/105223

§ 371 Date: May 1, 2025

(30) Foreign Application Priority Data
Aug. 14, 2023 (CN) 202311024311.7

(51) Int. Cl. H10H 29/49; H10H 29/01

(52) U.S. Cl. CPC H10H 29/49; H10H 29/012

(57) ABSTRACT

A light-emitting substrate includes a substrate, a plurality of connection leads, and at least one auxiliary connection portion. The substrate includes a first main surface and a second main surface that are opposite to each other in a thickness direction of the substrate, and side surfaces between the first main surface and the second main surface. The side surfaces include a set side surface. The plurality of connection leads are located on the substrate and extend from the first main surface to the second main surface via the set side surface, and each connection lead of at least one connection lead among the plurality of connection leads includes at least one opening. At least part of an auxiliary connection portion is located in the opening, and the auxiliary connection portion is connected to the connection lead where the opening is located.

### CROSS-REFERENCE TO RELATED APPLICATIONS

This application is the United States national phase of International Patent Application No. PCT/CN2024/105223, filed Jul. 12, 2024, and claims priority to Chinese Patent Application No. 202311024311.7, filed Aug. 14, 2023, the disclosures of which are hereby incorporated by reference in their entireties.

### BACKGROUND OF THE INVENTION

### Field of the Invention

The present disclosure relates to the field of display technologies, and in particular, to a light-emitting substrate and a display apparatus.

### Description of Related Art

Light-emitting diode (LED) chips include micro organic light-emitting diodes (Micro LEDs) and mini organic light-emitting diodes (Mini LEDs), which can be used to achieve seamless tiled display apparatuses. Mini/Micro LED display apparatuses have the characteristics such as high contrast, long life, and low power consumption.

At present, Mini/Micro LED display apparatuses, from small-size products with high precision to high-end large-screen products, have strong commercial demand and a wide range of application scenarios.

### SUMMARY OF THE INVENTION

In an aspect, a light-emitting substrate is provided. The light-emitting substrate includes a display region and a peripheral region located on at least one side of the display region. The light-emitting substrate further includes a substrate, and a plurality of connection leads and at least one auxiliary connection portion located on the substrate. The substrate includes a first main surface and a second main surface that are opposite to each other in a thickness direction of the substrate, and side surfaces between the first main surface and the second main surface. The side surfaces include a set side surface corresponding to the peripheral region. The plurality of connection leads are located on the substrate, and extend from the first main surface to the second main surface via the set side surface. The plurality of connection leads are located in the peripheral region, and each connection lead of at least one connection lead among the plurality of connection leads includes at least one opening. At least part of an auxiliary connection portion of the at least one auxiliary connection portion is located in the opening, and the auxiliary connection portion is connected to the connection lead where the opening is located.

In some embodiments, the auxiliary connection portion is located in the opening, and the auxiliary connection portion abuts against an edge of the connection lead that forms the opening.

In some embodiments, the auxiliary connection portion includes a main body portion and at least one lapping portion connected to the main body portion. The main body portion is located in the opening, the lapping portion is located on a side of the connection lead away from the substrate, and the lapping portion is in contact with the side of the connection lead away from the substrate.

In some embodiments, in a direction pointing from the main body portion to the lapping portion, a width of the lapping portion is greater than or equal to 10 μm.

In some embodiments, the connection lead includes three line segments connected in sequence; at least one line segment of the three line segments of the connection lead includes the at least one opening; the three line segments are a first line segment located on the first main surface, a third line segment located on the set side surface, and a second line segment located on the second main surface; the auxiliary connection portion is located on a line segment having an opening; and in an extending direction of the line segment having the opening, a length of the auxiliary connection portion is less than or equal to a length of the line segment having the opening.

In some embodiments, in an extending direction of the connection lead having the opening, a length of the auxiliary connection portion is less than or equal to a length of the connection lead having the opening.

In some embodiments, in a width direction of the connection lead, a ratio of a width of the at least part of the auxiliary connection portion located in the opening to a width of the opening is greater than or equal to 50%.

In some embodiments, a width of the auxiliary connection portion is in a range of 50 μm to 100 μm.

In some embodiments, an orthogonal projection of the auxiliary connection portion on the substrate covers an orthogonal projection of the opening on the substrate.

In some embodiments, an orthogonal projection of the auxiliary connection portion on the substrate covers an orthogonal projection of the connection lead having the opening on the substrate.

In some embodiments, a plurality of auxiliary connection portions are located in a same opening.

In some embodiments, the light-emitting substrate further includes first electrodes. The first electrodes are located on a side of the first main surface away from the second main surface. A first end of the connection lead is electrically connected to a first electrode, the first end includes an opening, and an orthogonal projection of the auxiliary connection portion on the substrate covers an orthogonal projection of the first electrode on the substrate.

In some embodiments, a first spacing between a border of the orthogonal projection of the auxiliary connection portion on the substrate and a border of the orthogonal projection of the first electrode on the substrate is less than or equal to 5 μm.

In some embodiments, a sheet resistance of the auxiliary connection portion is less than or equal to a sheet resistance of the connection lead.

In some embodiments, a thickness of the auxiliary connection portion is in a range of 5 μm to 20 μm.

In some other embodiments, a material of the auxiliary connection portion includes a conductive adhesive.

In some embodiments, the connection leads are metal wires.

In another aspect, a method for manufacturing a light-emitting substrate is provided. The light-emitting substrate includes a display region and a peripheral region located on at least one side of the display region. The method includes: providing a substrate, the substrate including: a first main surface and a second main surface that are opposite to each other in a thickness direction of the substrate, and side surfaces between the first main surface and the second main surface, where the side surfaces include a set side surface corresponding to the peripheral region; forming a plurality of connection leads in the peripheral region of the substrate, the plurality of connection leads extending from the first main surface to the second main surface via the set side surface, where each connection lead of at least one connection lead among the plurality of connection leads includes at least one opening; and forming at least one auxiliary connection portion on a side of the at least one connection lead away from the substrate, where at least part of an auxiliary connection portion of the at least one auxiliary connection portion is located in the opening, and the auxiliary connection portion is connected to the connection lead where the opening is located.

In some embodiments, forming the plurality of connection leads in the peripheral region of the substrate includes: forming the plurality of connection leads on the substrate through a sputtering process; and forming the at least one auxiliary connection portion on the side of the at least one connection lead away from the substrate includes: forming the at least one auxiliary connection portion on the side of the at least one connection lead away from the substrate through a three-dimensional printing process, so that the at least part of the auxiliary connection portion is located in the opening, and the auxiliary connection portion is connected to the connection lead where the opening is located.

In yet another aspect, a display apparatus is provided. The display apparatus includes the light-emitting substrate according to any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a display apparatus, in accordance with some other embodiments;

FIG. 3 is a structural diagram of a light exit surface of a light-emitting substrate, in accordance with some embodiments;

FIG. 4 is a structural diagram of a non-light exit surface of a light-emitting substrate, in accordance with some embodiments;

FIG. 5 is a sectional view of a light-emitting substrate, in accordance with some embodiments;

FIG. 6 is a structural diagram of a light-emitting substrate, in accordance with some embodiments;

FIG. 7 is a sectional view taken along the line B-B′ in FIG. 6;

FIG. 8 is a structural diagram of a first main surface of a light-emitting substrate, in accordance with some embodiments;

FIG. 9 is a sectional view taken along the line Q-Q′ in FIG. 8;

FIG. 10 is a structural diagram of a set side surface of a light-emitting substrate, in accordance with some embodiments;

FIG. 11 is a sectional view of a light-emitting substrate, in accordance with some embodiments;

FIG. 12 is a structural diagram of a second main surface of a light-emitting substrate, in accordance with some embodiments;

FIG. 13 is a sectional view taken along the line F-F′ in FIG. 12;

FIG. 14 is a structural diagram of a light-emitting substrate, in accordance with some other embodiments;

FIG. 15 is a structural diagram of a light-emitting substrate, in accordance with yet some other embodiments;

FIG. 16 is a sectional view taken along the line T-T′ in FIG. 15;

FIG. 17 is a structural diagram of a light-emitting substrate, in accordance with yet some other embodiments;

FIG. 18 is a structural diagram of a light-emitting substrate, in accordance with yet some other embodiments;

FIG. 19 is a structural diagram of a light-emitting substrate, in accordance with yet some other embodiments;

FIG. 20 is a sectional view of a light-emitting substrate, in accordance with some other embodiments;

FIG. 21 is a sectional view of a light-emitting substrate, in accordance with yet some other embodiments;

FIG. 22 is a structural diagram of a light-emitting substrate, in accordance with yet some other embodiments;

FIG. 23 is a structural diagram of a light-emitting substrate, in accordance with yet some other embodiments;

FIG. 24 is a structural diagram of a light-emitting substrate, in accordance with yet some other embodiments;

FIG. 25 is a sectional view taken along the line G-G′ in FIG. 24;

FIG. 26 is another sectional view taken along the line G-G′ in FIG. 24; and

FIG. 27 is a flow diagram of a method for manufacturing a light-emitting substrate, in accordance with some embodiments.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

Hereinafter, terms “first” and “second” are used for descriptive purposes only, and are not to be construed as indicating or implying a relative importance or implicitly indicating the number of indicated technical features. Thus, features defined with “first” or “second” may explicitly or implicitly include one or more of the features. In the description of the embodiments of the present disclosure, the term “multiple”, “a plurality of” or “the plurality of” means two or more unless otherwise specified.

Some embodiments may be described using the terms “coupled”, “connected” and their derivatives. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B, and C” has the same meaning as the phrase “at least one of A, B, or C”, both including the following combinations of A, B, and C: only A, only B, only C, a combination of A and B, a combination of A and C, a combination of B and C, and a combination of A, B, and C.

The phrase “A and/or B” includes the following three combinations: only A, only B, and a combination of A and B.

As used herein, the term “if” is, optionally, construed as “when” or “in a case where” or “in response to determining that” or “in response to detecting,” depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event].

The phrase “applicable to” or “configured to” used herein has an open and inclusive meaning, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or value exceeding those stated.

The term such as “about”, “substantially” or “approximately” as used herein includes a stated value and an average value within an acceptable range of deviation of a particular value, and the acceptable range of deviation is determined, for example, by a person of ordinary skill in the art, considering measurement in question and errors (i.e., limitations of a measurement system) associated with measurement of a particular quantity.

The term such as “parallel,” “perpendicular,” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be that, for example, a difference between the two that are equal is less than or equal to 5% of either of the two.

It will be understood that, when a layer or element is referred to as being on another layer or substrate, it may be that the layer or element is directly on the another layer or substrate, or it may be that intermediate layer(s) exist between the layer or element and the another layer or substrate.

Exemplary embodiments are described herein with reference to sectional views and/or plan views that are schematic illustrations of idealized embodiments. In the drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of the regions in a device, and are not intended to limit the scope of the exemplary embodiments.

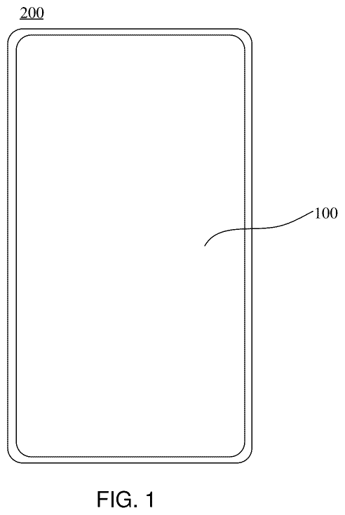

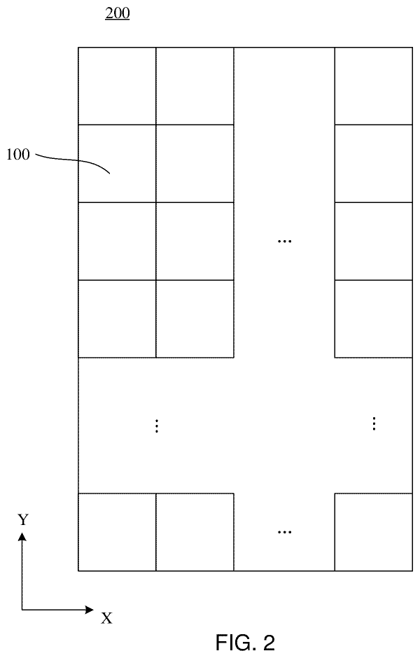

FIG. 1 is a structural diagram of a display apparatus, in accordance with some embodiments. FIG. 2 is a structural diagram of a display apparatus, in accordance with some other embodiments.

Referring to FIGS. 1 and 2, some embodiments of the present disclosure provide a display apparatus 200, and the display apparatus 200 includes a light-emitting substrate 100.

For example, the display apparatus 200 may be a liquid crystal display (LCD) apparatus, a mini light-emitting diode (Mini LED) display apparatus, or a micro light-emitting diode (Micro LED) display apparatus.

As shown in FIG. 1, in a case where the display apparatus 200 is a liquid crystal display apparatus, in some embodiments, the display apparatus 200 includes a cover glass, a liquid crystal display panel, and a backlight module. The backlight module is used to provide a light source for the liquid crystal display panel. The backlight module includes a light-emitting substrate 100, and the light-emitting substrate 100 provides light rays for the liquid crystal display panel, so that the liquid crystal display panel can display images. In some examples, the backlight module in the display apparatus 200 may further include optical films, and the optical films are located on a side of the light-emitting substrate 100 proximate to the liquid crystal display panel. The optical films may include a reflective sheet, a diffusion plate, a brightness enhancement film (prism sheet), a diffusion sheet, and the like, and may be used to improve brightness and uniformity of light rays.

As shown in FIG. 2, in a case where the display apparatus 200 is a Mini LED display apparatus or a Micro LED display apparatus, in some embodiments, the display apparatus 200 includes at least one light-emitting substrate 100, and the light-emitting substrate(s) 100 may realize image display.

In some examples, the display apparatus 200 may include a plurality of light-emitting substrates 100, and the plurality of light-emitting substrates 100 are tiled together to form the display apparatus 200. Alternatively, the display apparatus 200 may include one light-emitting substrate 100.

In some examples, the display apparatus 200 may further include an anti-reflection film layer and a protective cover plate. The anti-reflection film layer is located between the light-emitting substrate 100 and the protective cover plate. The anti-reflection film layer includes a polarizer, and the polarizer may be a circular polarizer. The polarizer can reduce reflection of external light, thus avoiding that the light-emitting panel 100 reflects ambient light to produce a dazzling effect.

For example, the display apparatus 200 may be any apparatus that can display images whether in motion (e.g., videos) or stationary (e.g., still images), and whether textual or graphical. More specifically, it is expected that the display apparatus in the embodiments may be implemented in or associated with various electronic devices, which include (but are not limit to), for example, a mobile phone, a wireless device, a personal digital assistant (PDA), a hand-held or portable computer, a GPS receiver/navigator, a camera, an MP4 video player, a video camera, a game console, a watch, a clock, a calculator, a TV monitor, a flat panel display, a computer monitor, a car display (e.g., an odometer display), a navigator, a cockpit controller and/or display, a display in camera view (e.g., a display for a rear camera in a vehicle), an electronic photo, an electronic billboard or indicator, a projector, a building structure, a packaging and an aesthetic structure (e.g., a display for an image of a piece of jewelry).

In some embodiments, the display apparatus 200 further includes a driver circuit board, and the driver circuit board is configured as a driver integrated circuit (IC) for driving the light-emitting substrate 100 to emit light and display images. The driver circuit board includes, for example, a gate driver circuit, a source driver circuit, a timing controller, and a power supply circuit. The driver circuit board is electrically connected to the light-emitting substrate 100 and is configured to output corresponding signals to control the light-emitting substrate 100 to emit light and display images.

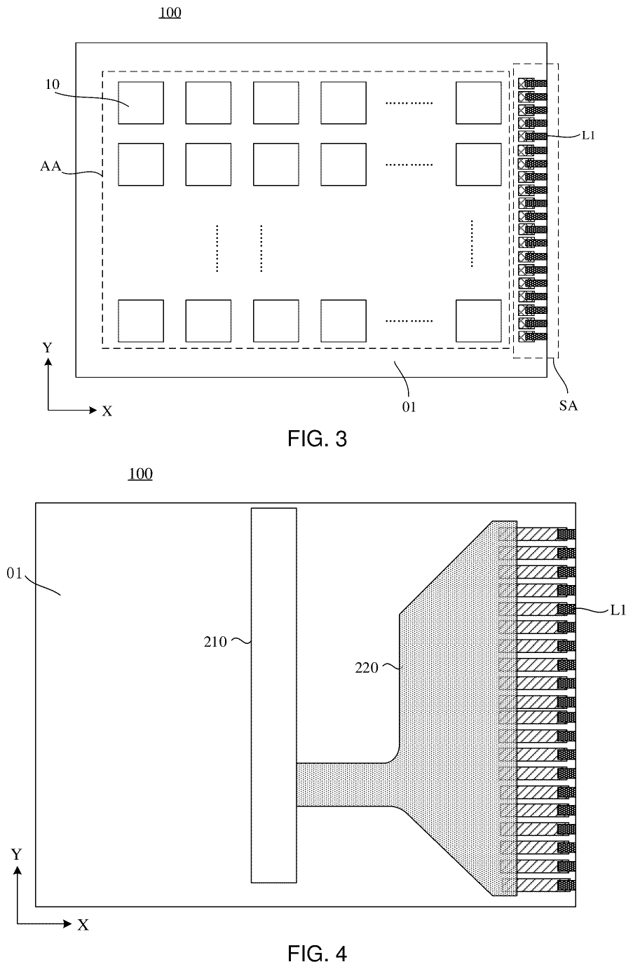

FIG. 3 is a structural diagram of a light exit surface of a light-emitting substrate, in accordance with some embodiments. FIG. 4 is a structural diagram of a non-light exit surface of a light-emitting substrate, in accordance with some embodiments.

Referring to FIGS. 3 and 4, some embodiments of the present disclosure provide a light-emitting substrate 100. The light-emitting substrate 100 includes a display region (also referred to as an active area (AA region for short), or an active display region) AA and a peripheral region SA. The peripheral region SA is located on at least one side (e.g., one side; or four sides, including upper and lower sides and left and right sides) of the display region AA. The light-emitting substrate 100 further includes a substrate 01 and a plurality of connection leads L1 located on the substrate 01.

In some examples, the substrate 01 may be a flexible substrate. For example, the substrate 01 is made of an organic material. For example, the substrate 01 is made of any one of polyimide (PI), polycarbonate (PC) and polyvinyl chloride (PVC).

In some other examples, the substrate 01 is a rigid substrate. For example, the rigid substrate is a glass substrate or a polymethyl methacrylate (PMMA) substrate.

In some examples, the display region AA includes a plurality of light-emitting chips 10, and the plurality of light-emitting chips 10 are located on the light exit surface of the light-emitting substrate 100.

For example, the light-emitting chips may be Micro LEDs or Mini LEDs. In this embodiment, the light-emitting chips 10 can emit light, thus being applied to apparatuses such as display apparatuses and lighting devices.

In the case where the display apparatus 200 is the liquid crystal display apparatus, in some examples, the light-emitting substrate 100 is a backlight source of the display apparatus 200, which is used to provide a light source for the liquid crystal display apparatus. Each light-emitting chip 10 can be controlled independently; thus, the display apparatus can realize local dimming, achieve a high-dynamic range (HDR) effect, and improve the display quality of the display apparatus 200.

In the case where the display apparatus 200 is the Mini LED display apparatus or the Micro LED display apparatus, in some examples, the light-emitting chips 10 (e.g., Micro LEDs, Mini LEDs, etc.) can emit light to directly display images.

For example, the light-emitting chips 10 may be light-emitting elements capable of emitting light of the same color, e.g., may all be blue LEDs, red LEDs, green LEDs or yellow LEDs. Thus, the display apparatus 200 may be a single-color display apparatus, which may be an instrument dial, a signal indicator screen, or other apparatuses.

For example, the light-emitting chips 10 may include various light-emitting elements of different colors, e.g., including at least two of red LEDs, green LEDs, blue LEDs and yellow LEDs. Light-emitting elements E of different colors may be independently controlled. In this way, the display apparatus 200 can perform color display by mixing light.

In some examples, the plurality of light-emitting chips 10 in the light-emitting substrate 10 are arranged in a plurality of rows and a plurality of columns. For convenience of description, the plurality of light-emitting chips 10 in the present disclosure are described by taking an example in which the plurality of light-emitting chips 10 are arranged in an array.

For example, the plurality of light-emitting chips 10 in the light-emitting substrate 100 are arranged in an array with equal spacing in a first direction (row direction) X and a second direction (column direction) Y. In this way, the uniformity of the distribution of the light-emitting chips 10 in the light-emitting substrate 100 may be improved.

In some examples, the first direction X and the second direction Y may be approximately perpendicular to each other. In this case, an included angle between the first direction X and the second direction Y is approximately equal to 90°. For example, the included angle between the first direction X and the second direction Y is 85°, 90°, or 95°.

The plurality of connection leads L1 in the light-emitting substrate 100 are located in the peripheral region SA. The light-emitting chips 10 located on the light exit surface of the light-emitting substrate 100 can be electrically connected to the driver circuit board 210 through the connection leads L1. That is, the connection leads L1 in the light-emitting substrate 100 can transmit driving signals provided by the driver circuit board 210 to the light-emitting chips 10 in the light-emitting substrate 100 to drive the light-emitting chips 10 to emit light, thereby realizing the image display of the light-emitting substrate 100.

For example, the driver circuit board 210 is electrically connected to the connection leads L1 through a flexible printed circuit (FPC) 220.

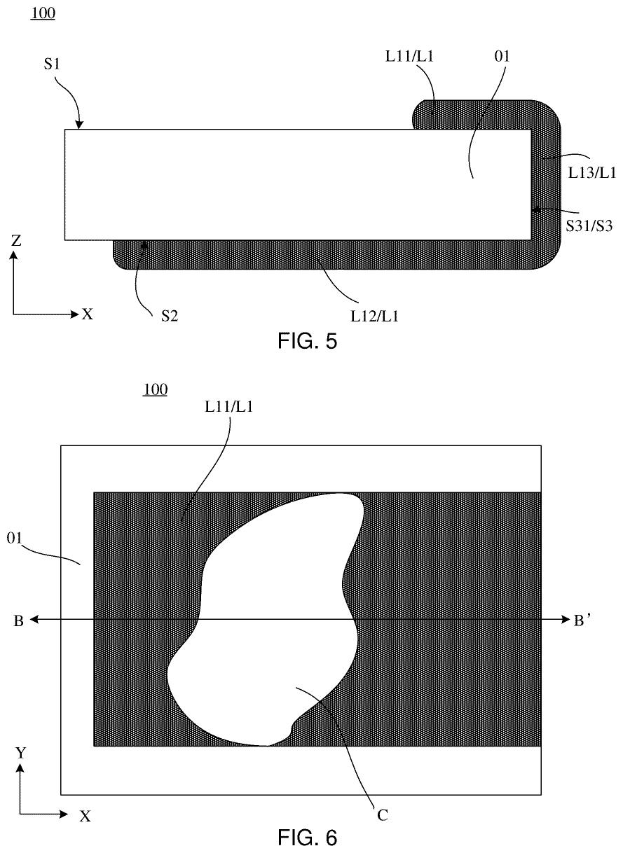

FIG. 5 is a sectional view of a light-emitting substrate, in accordance with some embodiments.

In some embodiments, referring to FIGS. 3 to 5, the substrate 01 in the light-emitting substrate 100 includes a first main surface S1 and a second main surface S2 opposite to each other in a thickness direction Z of the substrate 01, and side surface(s) S3 located between the first main surface S1 and the second main surface S2. The side surface(s) S3 are used to be connected to the first main surface S1 and the second main surface S2.

For example, the substrate 01 includes a plurality of side surfaces S3, and the plurality of side surfaces S3 are used to be connected to the first main surface S1 and the second main surface S2. For example, the substrate 01 is in a shape of a cuboid, and the first main surface S1 and the second main surface S2 of the substrate 01 are rectangular. In this case, the substrate 01 includes four side surfaces S3.

The plurality of side surfaces S3 include a set side surface S31 corresponding to the peripheral region SA. It will be noted that the “set side surface S31” refers to a side surface corresponding to the peripheral region SA among the plurality of side surfaces S3 of the substrate 01.

In some examples, the driver circuit board 210 may be located on a side of the second main surface S2 away from the first main surface S1. That is, the driver circuit board 210 is located on the non-light exit of the light-emitting substrate 100. Based on this, the plurality of connection leads L1 may be arranged to extend from the first main surface S1 to the second main surface S2 via the set side surface S31.

Based on the above structure, it represents that the connection lead L1 includes three line segments respectively located on the first main surface S1, the second main surface S2 and the set side surface S31. The three line segments are a first line segment L11 located on the first main surface S1, a second line segment L12 located on the second main surface S2, and a third line segment L13 located on the set side surface S31. The third line segment L13 is connected to the first line segment L11 and the second line segment L12 to form the connection lead L1.

In this way, the driver circuit board may be arranged on the second main surface S2 of the substrate 01. That is, a bonding region of the light-emitting substrate 100 may be arranged on the second main surface S2 of the substrate 01. The first line segment L11 of the connection lead L1 is electrically connected to the light-emitting chip 10, and the second line segment L12 is electrically connected to the driver circuit board, so that the light-emitting chip 10 is electrically connected to the driver circuit board. Based on this, the connection lead L1 can be used to transmit the driving signal provided by the driver circuit board to the light-emitting chip 10 of the light-emitting substrate 100, so as to control the light-emitting substrate 100 to display images.

In addition, since the driver circuit board is arranged on the second main surface S2 of the substrate 01, when the light-emitting substrate 100 is subjected to a bonding process, there is no need to perform a bending bonding process at an edge of the light-emitting substrate 100, which is conducive to achieving a narrow bezel of the light-emitting substrate 100. This may be widely used in tiled application products.

In some examples, the thickness direction Z of the substrate 01 is approximately perpendicular to the first direction X. In this case, an included angle between the thickness direction Z of the substrate 01 and the first direction X is approximately equal to 90°. For example, the included angle between the thickness direction Z of the substrate 01 and the first direction X is 85°, 90°, or 95°.

Furthermore, the thickness direction Z of the substrate 01 is approximately perpendicular to the second direction Y. In this case, an included angle between the thickness direction Z of the substrate 01 and the second direction Y is approximately equal to 90°. For example, the included angle between the thickness direction Z of the substrate 01 and the second direction Y is 85°, 90°, or 95°.

In some examples, the connection lead L1 is a metal wire. Based on this, the metal wires can transmit the driving signals provided by the driver circuit board to the light-emitting substrate 100, so as to control the light-emitting substrate 100 to display images.

In some examples, the connection lead L1 may be a stacked-layer metal wire. In this way, the connection lead may have good conductivity, and its service life may be prolonged.

The stacked-layer metal wire includes a base layer, a functional layer and a protective layer, and the functional layer is located between the protective layer and the base layer.

The functional layer in the stacked-layer metal wire may be selected from copper, aluminum, molybdenum, etc. Considering that copper has lower resistance in practical applications, the functional layer may be made of copper.

The base layer and the protective layer in the stacked-layer metal wire may be made of inert metal or other alloy materials, e.g., titanium, nickel-chromium alloy, etc.

For example, the stacked-layer metal wire may be a Ti/Al/Ti stacked metal wire. However, the embodiments of the present disclosure are not limited thereto.

In some examples, a thickness of the connection lead L1 is in a range of 0.5 μm to 4 μm.

In the case where the thickness of the connection lead L1 is equal to or approaches 0.5 μm, the thickness of the connection lead L1 is small, so that the connection lead L1 may be attached to the substrate 01 more closely, and the risk of the connection lead L1 being detached from the substrate 01 is reduced. In addition, in the case where the thickness of the connection lead L1 is equal to or approaches 0.5 μm, it may avoid a problem that the connection lead L1 has high resistance due to the small thickness of the connection lead L1. Furthermore, it may be conducive to reducing the attenuation of the signal transmitted by the connection lead L1 caused by the resistance of the connection lead L1, and may be conducive to improving the display quality of the light-emitting substrate 100.

In the case where the thickness of the connection lead L1 is equal to or approaches 4 μm, the thickness of the connection lead L1 is large, so that the resistance of the connection lead L1 may be low. Therefore, it may be conducive to reducing the attenuation of the signal transmitted by the connection lead L1 caused by the resistance of the connection lead L1, and may be conducive to improving the display quality of the light-emitting substrate 100. In addition, in the case where the thickness of the connection lead L1 is equal to or approaches 4 μm, it may be possible to avoid that the risk of the connection lead L1 being detached from the substrate 01 is increased due to the excessive thickness of the connection lead L1.

In some examples, the thickness of the connection lead L1 is in a range of 1 μm to 2 μm.

In the case where the thickness of the connection lead L1 is equal to or approaches 1 μm, the connection lead L1 may be attached to the substrate 01 more closely, and the risk of the connection lead L1 being detached from the substrate 01 is reduced; in addition, it may also avoid a high resistance of the connection lead L1, and in turn reduce the attenuation of the signal transmitted by the connection lead L1 caused by the resistance of the connection lead L1.

In the case where the thickness of the connection lead L1 is equal to or approaches 2 μm, the resistance of the connection lead L1 may be small, which may reduce the attenuation of the signal transmitted by the connection lead L1 caused by the resistance of the connection lead L1; in addition, it may be possible to avoid that the risk of the connection lead L1 being detached from the substrate 01 is increased due to the excessive thickness of the connection lead L1.

For example, the thickness of the connection lead L1 is approximately any one of 0.5 μm, 1 μm, 1.5 μm, 2 μm, 2.5 μm, 3 μm, 3.5 μm, or 4 μm. However, the embodiments of the present disclosure are not limited thereto.

Considering an example in which the thickness of the connection lead L1 is approximately 1 μm for introduction, it may be possible to mitigate the problem of the connection lead L1 being detached from the substrate 01, and may also ameliorate the attenuation of the signal transmitted by the connection lead L1 caused by the resistance of the connection lead L1.

It will be noted that, due to certain uncontrollable errors (such as manufacturing process errors, equipment accuracy, measurement errors, etc.), in a case where an error of the thickness of the connection lead L1 fluctuates within a range of 10%×1 μm, it will also be considered that the thickness of the connection lead L1 satisfies a condition of being equal to 1 μm.

In addition, in some other examples, due to certain uncontrollable errors (such as manufacturing process errors, equipment accuracy, measurement errors, etc.), in a case where an error of the thickness of the connection lead L1 fluctuates within a range of 5%×1 μm, it will also be considered that the thickness of the connection lead L1 satisfies a condition of being equal to 1 μm.

In some examples, the plurality of connection leads L1 and the plurality of light-emitting chips 10 may be coupled in a one-to-one correspondence. In some other examples, a single connection lead L1 may be coupled to multiple light-emitting chips 10, or multiple connection leads L1 may be coupled to a single light-emitting chip 10.

In the present disclosure, the structure of the display apparatus 200 will be schematically described below by taking an example in which a single connection lead L1 is coupled to multiple light-emitting chips 10.

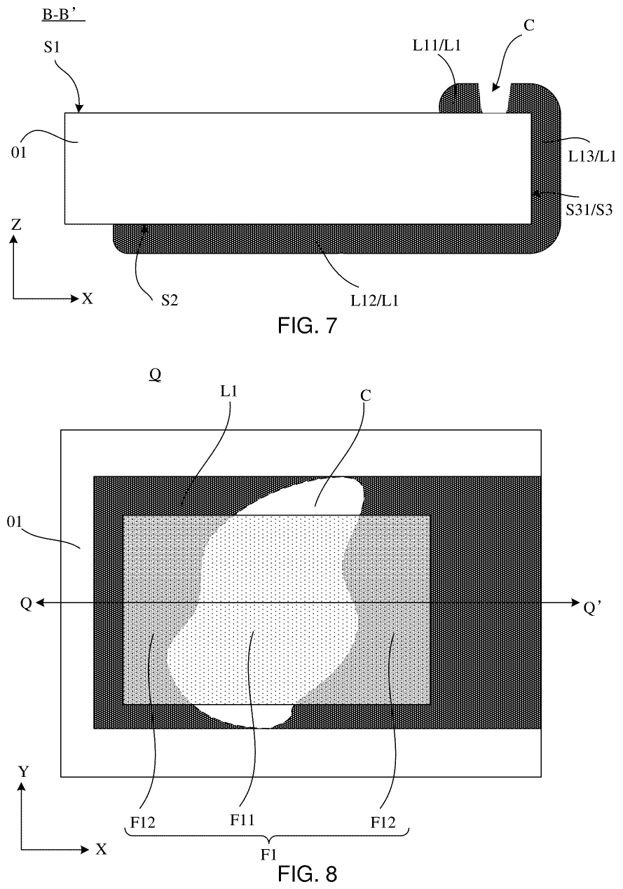

FIG. 6 is a structural diagram of a light-emitting substrate, in accordance with some embodiments. FIG. 7 is a sectional view taken along the line B-B′ in FIG. 6. FIG. 6 shows a structure of a first line segment of a connection lead. As for the structures of other line segments of the connection lead which are similar to the structure of the first line segment, reference can be made to the introduction of the structure of the first line segment, and the structures of other line segments of the connection lead will also be described in detail below. In addition, in order to illustrate the structure of the connection lead in FIG. 6, the substrate below the connection lead is also illustrated.

The inventors have found through research that, referring to FIGS. 6 and 7, after the connection leads L1 in the light-emitting substrate 100 are formed, the connection leads L1 have high disconnection rate, resulting in a low yield of the connection leads L1. The main reason for the low yield of the connection leads L1 is that the existing manufacturing process cannot meet the environmental cleanliness requirement of the connection leads L1, which will cause a part of the connection lead L1 to fall off to form an opening C, and the opening C affects the yield of the connection leads L1.

For example, the connection leads L1 may fall off in spots, at edges, or over large areas, and the above-mentioned falling off situations will result in openings C of different shapes and sizes in the connection leads L1. Regardless of the types of the openings C, the quality of the connection leads L1 will be reduced, and the yield of the connection leads L1 will also be reduced.

It will be noted that the opening C in the connection lead L1 is formed since a part of the connection lead L1 naturally falls off from the substrate 01, and it is not a gap formed by human operation or design. Furthermore, the shape of the opening C cannot be guaranteed. The opening C may be of a regular shape, such as circle, square, polygon, etc. Alternatively, the opening C may be of an irregular shape.

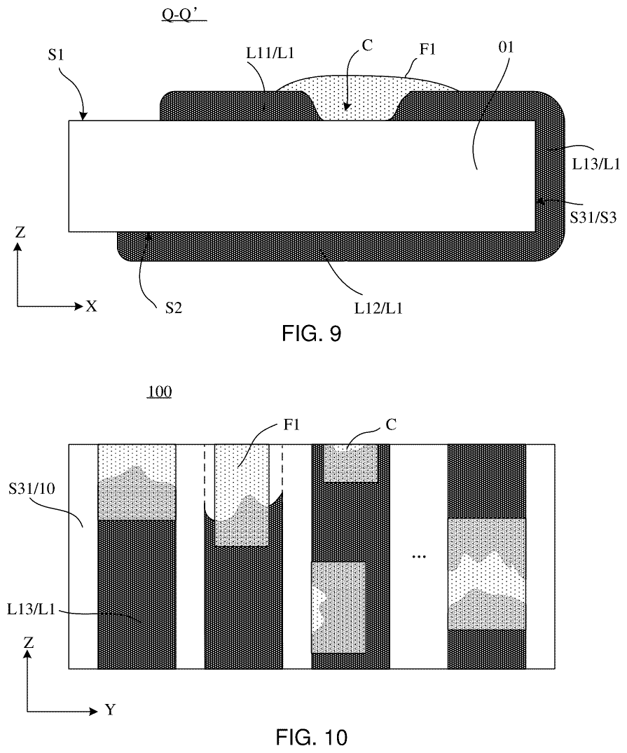

FIG. 8 is a structural diagram of a first main surface of a light-emitting substrate, in accordance with some embodiments. FIG. 9 is a sectional view taken along the line Q-Q′ in FIG. 8. FIG. 8 shows a structure of a first line segment of a connection lead. As for the structures of other line segments of the connection lead which are similar to the structure of the first line segment, reference can be made to the introduction of the structure of the first line segment, and the structures of other line segments of the connection lead will also be described in detail below. In addition, in order to illustrate the structure of the connection lead in FIG. 8, the substrate below the connection lead is also illustrated.

In view of the above problems, referring to FIGS. 8 and 9, in the light-emitting substrate 100 provided in the embodiments of the present disclosure, at least one connection lead L1 among the plurality of connection leads L1 includes an opening. The light-emitting substrate 100 further includes auxiliary connection portion(s) F1. At least part of the auxiliary connection portion F1 is disposed in an opening C, and the auxiliary connection portion F1 is connected to a connection lead L1 where the opening C is located.

Based on this, in the case where there is a connection lead L1 having at least one opening C among the plurality of connection leads L1 in the light-emitting substrate 100, the auxiliary connection portion F1 may patch the opening C formed by the falling off of the connection lead L1. That is, the auxiliary connection portion F1 may replace the fallen-off part of the connection lead L1, so that the connection lead L1 can maintain normal circuit conduction. Therefore, the yield of the connection leads L1 may be improved.

The above description that “at least part of the auxiliary connection portion F1 is disposed in an opening C” may include the following:

The first arrangement is that the entire auxiliary connection portion F1 is arranged in the opening C. In this case, the auxiliary connection portion F1 may be disposed in the opening C and attached to the connection lead L1 having the opening C, so that the auxiliary connection portion F1 is electrically connected to the connection lead L1.

The second arrangement is that a part of the auxiliary connection portion F1 is arranged in the opening C. In this case, a remaining part of the auxiliary connection portion F1 may be located on the connection lead L1 having the opening C, so that the auxiliary connection portion F1 is electrically connected to the connection lead L1.

Regardless of which of the above-mentioned arrangements of the auxiliary connection portion F1 is used, the auxiliary connection portion F1 can be used to replace the fallen-off part of the connection lead L1, so that the connection lead L1 can maintain normal circuit conduction. Therefore, the yield of the connection leads L1 may be improved.

In summary, in the light-emitting substrate 100 provided in the embodiments of the present disclosure, the auxiliary connection portion F1 is arranged such that at least part of the auxiliary connection portion F1 is disposed in the opening C. Therefore, the auxiliary connection portion F1 replaces the fallen-off part of the connection lead L1, and the connection lead L1 can maintain normal circuit conduction. As a result, the yield of the connection leads L1 may be improved.

In some embodiments, with continued reference to FIGS. 8 and 9, the plurality of connection leads L1 are arranged to extend from the first main surface S1 to the second main surface S2 via the set side surface S31. That is, the connection lead L1 includes: a first line segment L11 located on the first main surface S1, a third line segment L13 located on the set side surface S31, and a second line segment L12 located on the second main surface S2, which are sequentially connected. The third line segment L13 is connected to the first line segment L11 and the second line segment L12 to form the connection lead L1.

After the connection leads L1 are formed on the substrate 01, the connection lead L1 may have an opening C on any surface (the first main surface S1, the set side surface S31, and the second main surface S2) of the substrate 01. That is, each of the first line segment L11, the second line segment L12, and the third line segment L13 in the connection lead L1 may partially fall off to form at least one opening C.

That is, the opening(s) C may be located in at least one of the first line segment L11, the second line segment L12, and the third line segment L13. However, the opening C in any line segment of the connection lead L1 will affect the yield of the connection lead L1.

In view of the above problem, an auxiliary connection portion F1 can be arranged on a line segment with an opening C, so that the auxiliary connection portion F1 is used to patch the line segment, which ensures that a connection lead L1 including the line segment maintains normal circuit conduction to improve the yield of the connection lead L1. The following description will introduce a scenario in which each line segment of the connection lead L1 has an opening C with reference to relevant drawings.

In some examples, with continued reference to FIGS. 8 and 9, an extending direction of the first line segment L11 of the connection lead L1 located on the first main surface S1 of the substrate 01 may be parallel to the first direction X. An end of the first line segment L11 is electrically connected to the light-emitting chip 10, and another end of the first line segment L11 is electrically connected to the third line segment L13 disposed on the set side surface S31. A first line segment L11 of each of at least one connection lead L1 may include at least one opening C. The term “parallel” includes absolute parallelism and approximate parallelism, and an acceptable range of deviation of the approximate parallelism may be, for example, a deviation within 5°.

Based on this, the auxiliary connection portion F1 can be formed on the first main surface S1, so that the auxiliary connection portion F1 is arranged on the first line segment L11. At least part of the auxiliary connection portion F1 is located in the opening C of the first line segment L11, so that the auxiliary connection portion F1 is electrically connected to the first line segment L11 having the opening C. Furthermore, the auxiliary connection portion F1 may be used to patch the opening C formed in the first line segment L11, so that the auxiliary connection portion F1 replaces the fallen-off part of the connection lead L1. Therefore, the connection lead L1 can maintain normal circuit conduction. As a result, the yield of the connection leads L1 may be improved.

It will be noted that the auxiliary connection portion F1 is arranged on the first line segment L11, which can be understood that the auxiliary connection portion F1 is arranged corresponding to a position of the opening C in the first line segment L11. For example, after the connection lead L1 is formed, the auxiliary connection portion F1 is formed at the position of the opening C of the connection lead L1. That is to say, at least part of the auxiliary connection portion F1 is within the opening C. That is, the at least part of the auxiliary connection portion F1 is not formed on the first line segment L11, but is formed on a part of the substrate 01 exposed by the opening C.

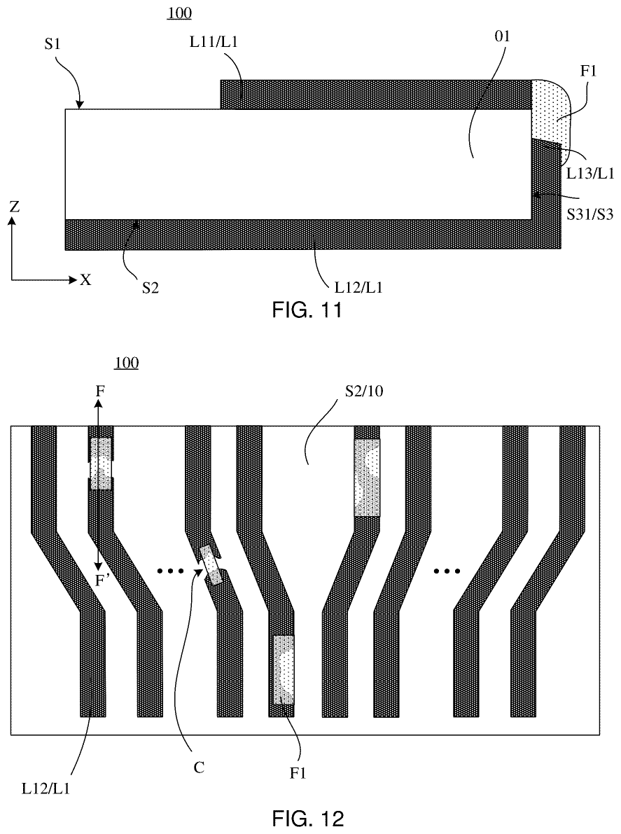

FIG. 10 is a structural diagram of a set side surface of a light-emitting substrate, in accordance with some embodiments. FIG. 11 is a sectional view of a light-emitting substrate, in accordance with some embodiments. FIG. 10 shows a structure of multiple second line segments of connection leads. FIG. 11 may be a sectional view of the light-emitting substrate 100 shown in FIG. 10, and illustrates a first connection lead L1 (a third line segment L13) on the left of FIG. 10 as an example.

In some examples, referring to FIGS. 10 and 11, an extending direction of the third line segment L13 of the connection lead L1 located on the set side surface S31 of the substrate 01 may be parallel to the thickness direction Z of the substrate 01. Two ends of the third line segment L13 may be electrically connected to the first line segment L11 and the second line segment L12, respectively. A third line segment L13 of each of at least one connection lead L1 may include at least one opening C. The term “parallel” includes absolute parallelism and approximate parallelism, and an acceptable range of deviation of the approximate parallelism may be, for example, a deviation within 5°.

Based on this, the auxiliary connection portion F1 can be formed on the set side S, so that the auxiliary connection portion F1 is arranged on the third line segment L13, and at least part of the auxiliary connection portion F1 is located in the opening C of the third line segment L13. Thus, the auxiliary connection portion F1 may be used to patch the opening C formed in the third line segment L13, and the auxiliary connection portion F1 replaces the fallen-off part of the connection lead L1. Therefore, the connection lead L1 can maintain normal circuit conduction. As a result, the yield of the connection leads L1 may be improved.

It will be noted that the auxiliary connection portion F1 is arranged on the third line segment L13, which can be understood that after the connection lead L1 is formed, the auxiliary connection portion F1 is formed at the position of the opening C of the connection lead L1. That is to say, at least part of the auxiliary connection portion F1 is within the opening C. That is, the at least part of the auxiliary connection portion F1 is not formed on the third line segment L13, but is formed on a part of the substrate 01 exposed by the opening C.

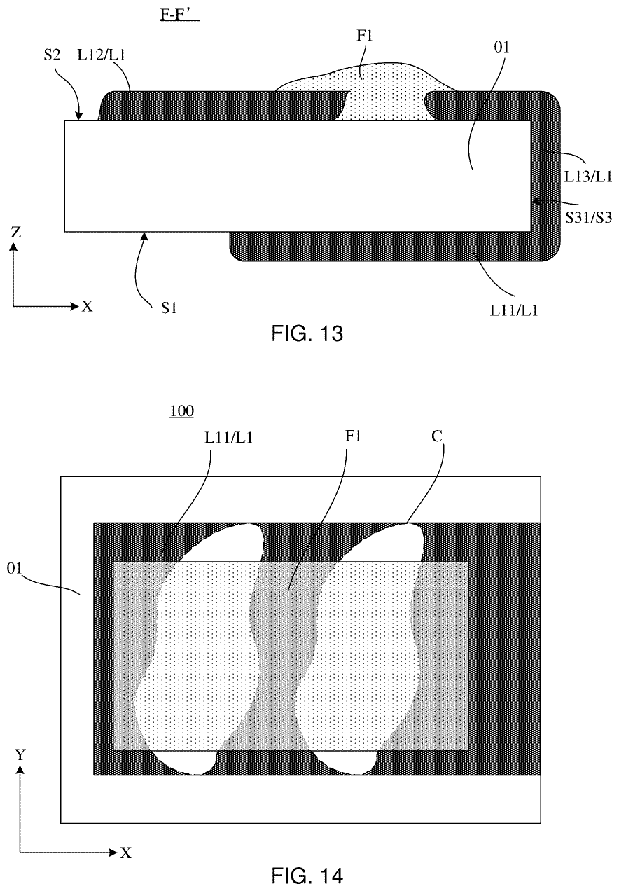

FIG. 12 is a structural diagram of a second main surface of a light-emitting substrate, in accordance with some embodiments. FIG. 13 is a sectional view taken along the line F-F′ in FIG. 12.

In some examples, referring to FIGS. 12 and 13, the second line segment L12 of the connection lead L1 has at least one opening C.

Based on this, the auxiliary connection portion F1 can be formed on the second main surface S2, so that the auxiliary connection portion F1 is arranged on the second line segment L12. At least part of the auxiliary connection portion F1 is located in the opening C of the second line segment L12, so that the auxiliary connection portion F1 is electrically connected to the second line segment L12 having the opening C. Furthermore, the auxiliary connection portion F1 may be used to patch the opening C formed in the second line segment L12, and the auxiliary connection portion F1 replaces the fallen-off part of the connection lead L1. Therefore, the connection lead L1 can maintain normal circuit conduction. As a result, the yield of the connection leads L1 may be improved.

It will be noted that the auxiliary connection portion F1 is arranged on the second line segment L12, which can be understood that after the connection lead L1 is formed, the auxiliary connection portion F1 is formed at the position of the opening C of the connection lead L1. That is to say, at least part of the auxiliary connection portion F1 is within the opening C. That is, the at least part of the auxiliary connection portion F1 is not formed on the second line segment L12, but is formed on a part of the substrate 01 exposed by the opening C.

In summary, no matter which line segment of the connection lead L1 in the light-emitting substrate 100 partially falls off, an auxiliary connection portion F1 may be formed on the surface corresponding to the line segment, so that at least part of the auxiliary connection portion F1 is arranged in the opening C of the line segment. That is, the auxiliary connection portion F1 is used to replace the fallen-off part of the connection lead L1, so that the connection lead L1 can maintain normal circuit conduction.

In some examples, the second line segment L12 of the connection lead L1 is formed on the second main surface S2, and the driver circuit board 210 in the display apparatus 200 (as shown in FIG. 4) may also be located on the second main surface S2. Based on this, the second line segment L12 of the connection lead L1 can be electrically connected to the driver circuit board 210 to receive the signal provided by the driver circuit board 210 and to transmit the signal to the light-emitting chip 10 in the display region AA, thereby realizing the light emission and display of the light-emitting substrate 100.

For example, second line segments L12 of the plurality of connection leads L1 may converge from a side close to the set side surface S31 (a side away from the driver circuit board) to a side away from the set side surface S31 (a side close to the driver circuit board), so as to facilitate electrical connection between the second line segments L12 of the connection leads L1 and the driver circuit board 210.

The above embodiments describe the scenarios in which any one line segment of the connection lead L1 has an opening C. The following description will introduce scenarios in which each of at least two line segments of the connection lead L1 have at least one opening C.

In some examples, any two of the first line segment L11, the second line segment L12, and the third line segment L13 of the connection lead L1 may each include at least one opening C.

The above structure may include the following three situations.

In the first situation, the first line segment L11 and the second line segment L12 each include at least one opening C.

In the second situation, the first line segment L11 and the third line segment L13 each include at least one opening C.

In the third situation, the second line segment L12 and the third line segment L13 each include at least one opening C.

For the above first situation:

For example, when each of the first line segment L11 and the second line segment L12 includes at least one opening C, an auxiliary connection portion F1 may be arranged corresponding to the opening C in the first line segment L11, and an auxiliary connection portion F1 may be arranged corresponding to the opening C in the second line segment L12.

Based on the above structure, two different auxiliary connection portions F1 respectively patch the first line segment L11 and the second line segment L12, so that a size and shape of each auxiliary connection portion F1 may be set correspondingly to a size and shape of an opening C in a line segment (the first line segment L11 or the second line segment L12) that the auxiliary connection portion F1 patches. Therefore, the auxiliary connection portion F1 may accurately patch the line segment (the first line segment L11 or the second line segment L12) of the connection lead L1. In addition, the auxiliary connection portion F1 is only provided for the line segment having the opening C (the first line segment L11 or the second line segment L12), which means that there is no need to provide an auxiliary connection portion F1 at the position of the intact third line segment L13 without an opening C, which may facilitate saving resources.

Alternatively, an auxiliary connection portion F1 may be provided, which may overlap with both the opening C in the first line segment L11 and the opening C in the second line segment L12, so that the auxiliary connection portion F1 may be used to patch both the first line segment L11 and the second line segment L12 at the same time. It can be understood that, at this time, the auxiliary connection portion F1 also extends across the third line segment L13 located between the first line segment L11 and the second line segment L12.

Based on the above structure, the size of the auxiliary connection portion F1 in the case where one auxiliary connection portion F1 patches both the first line segment L11 and the second line segment L12 is greater than the size of the auxiliary connection portion F1 in the case where two different auxiliary connection portions F1 respectively patch the first line segment L11 and the second line segment L12. Therefore, in the case where the same auxiliary connection portion F1 is used to patch both the first line segment L11 and the second line segment L12, the size of the auxiliary connection portion F1 is large, which may be conducive to increasing a lapping area of the auxiliary connection portion F1 and the connection lead L1 and improving of the stability of the connection between the auxiliary connection portion F1 and the connection lead L1, and in turn ensures the yield of the connection lead.

For the above second situation:

For example, when each of the first line segment L11 and the third line segment L13 includes at least one opening C, an auxiliary connection portion F1 may be arranged corresponding to the opening C in the first line segment L11, and an auxiliary connection portion F1 may be arranged corresponding to the opening C in the third line segment L13.

Based on the above structure, two different auxiliary connection portions F1 respectively patch the first line segment L11 and the third line segment L13, so that a size and shape of each auxiliary connection portion F1 may be set correspondingly to a size and shape of an opening C in a line segment (the first line segment L11 or the third line segment L13) that the auxiliary connection portion F1 patches. Therefore, the auxiliary connection portion F1 may accurately patch the line segment (the first line segment L11 or the third line segment L13) of the connection lead L1. In addition, the auxiliary connection portion F1 is only provided for the line segment having the opening C (the first line segment L11 or the third line segment L13), which may facilitate saving resources.

Alternatively, since the first line segment L11 and the third line segment L13 are connected, an auxiliary connection portion F1 may be provided, which may overlap with both the opening C in the first line segment L11 and the opening C in the third line segment L13. Thus, the auxiliary connection portion F1 may be used to patch both the first line segment L11 and the third line segment L13 at the same time.

Based on the above structure, the size of the auxiliary connection portion F1 in the case where one auxiliary connection portion F1 patches both the first line segment L11 and the third line segment L13 is greater than the size of the auxiliary connection portion F1 in the case where two different auxiliary connection portions F1 respectively patch the first line segment L11 and the third line segment L13. Therefore, in the case where the same auxiliary connection portion F1 is used to patch both the first line segment L11 and the third line segment L13, the size of the auxiliary connection portion F1 is large, which may be conducive to increasing a lapping area of the auxiliary connection portion F1 and the connection lead L1 and improving of the stability of the connection between the auxiliary connection portion F1 and the connection lead L1, and in turn ensures the yield of the connection lead.

In addition, the auxiliary connection portion F1 is arranged to overlap with both the opening C in the first line segment L11 and the opening C in the third line segment L13, which means that the auxiliary connection portion F1 includes a portion located on the first main surface S1 and a portion located on the set side surface S31 that are connected. Since the portion located on the first main surface S1 is connected to the portion located on the set side surface S31, it may be conducive to reducing the probability of an end, close to the first main surface S1, of the auxiliary connection portion F1 on the set side surface S31 falling off from the substrate 01 (the third line segment L13).

For the above third situation:

For example, when each of the second line segment L12 and the third line segment L13 includes at least one opening C, an auxiliary connection portion F1 may be arranged corresponding to the opening C in the second line segment L12, and an auxiliary connection portion F1 may be arranged corresponding to the opening C in the third line segment L13.

Based on the above structure, two different auxiliary connection portions F1 respectively patch the second line segment L12 and the third line segment L13, so that a size and shape of each auxiliary connection portion F1 may be set correspondingly to a size and shape of an opening C in a line segment (the second line segment L12 and the third line segment L13) that the auxiliary connection portion F1 patches. Therefore, the auxiliary connection portion F1 may accurately patch the line segment (the second line segment L12 and the third line segment L13) of the connection lead L1. In addition, the auxiliary connection portion F1 is only provided for the line segment having the opening C (the second line segment L12 and the third line segment L13), which may facilitate saving resources.

Alternatively, since the second line segment L12 and the third line segment L13 are connected, an auxiliary connection portion F1 may be provided, which may overlap with both the opening C in the second line segment L12 and the opening C in the third line segment L13. Thus, the auxiliary connection portion F1 may be used to patch both the second line segment L12 and the third line segment L13 at the same time.

Based on the above structure, the size of the auxiliary connection portion F1 in the case where one auxiliary connection portion F1 patches both the second line segment L12 and the third line segment L13 is greater than the size of the auxiliary connection portion F1 in the case where two different auxiliary connection portions F1 respectively patch the second line segment L12 and the third line segment L13. Therefore, in the case where the same auxiliary connection portion F1 is used to patch both the second line segment L12 and the third line segment L13, the size of the auxiliary connection portion F1 is large, which may be conducive to increasing a lapping area of the auxiliary connection portion F1 and the connection lead L1 and improving of the stability of the connection between the auxiliary connection portion F1 and the connection lead L1, and in turn ensures the yield of the connection lead.

In addition, the auxiliary connection portion F1 is arranged to overlap with both the opening C in the second line segment L12 and the opening C in the third line segment L13, which means that the auxiliary connection portion F1 includes a portion located on the second main surface S2 and a portion located on the set side surface S31 that are connected. Since the portion located on the second main surface S2 is connected to the portion located on the set side surface S31, it may be conducive to reducing the probability of an end, close to the second main surface S2, of the auxiliary connection portion F1 on the set side surface S31 falling off from the substrate 01 (the third line segment L13).

In some other examples, each of the first line segment L11, the second line segment L12, and the third line segment L13 in the connection lead L1 may include at least one opening C.

In this case, an auxiliary connection portion F1 may be arranged corresponding to the opening C in the first line segment L11, an auxiliary connection portion F1 may be arranged corresponding to the opening C in the second line segment L12, and an auxiliary connection portion F1 may be arranged corresponding to the opening C in the third line segment L13.

Based on the above structure, three different auxiliary connection portions F1 patch the first line segment L11, the second line segment L12 and the third line segment L13, so that a size and shape of each auxiliary connection portion F1 may be set correspondingly to a size and shape of an opening C in a line segment (the first line segment L11, the second line segment L12 or the third line segment L13) that the auxiliary connection portion F1 patches. Therefore, the auxiliary connection portion F1 may accurately patch the line segment (the first line segment L11, the second line segment L12, or the third line segment L13) of the connection lead L1. In addition, the auxiliary connection portion F1 is only provided for the line segment having the opening C (the first line segment L11, the second line segment L12 or the third line segment L13), which may facilitate saving resources.

Alternatively, an auxiliary connection portion F1 may be provided, which may overlap with the opening C in the first line segment L11, the opening C in the second line segment L12 and the opening C in the third line segment L13 at the same time. Thus, the auxiliary connection portion F1 may be used to simultaneously patch the first line segment L11, the second line segment L12 and the third line segment L13.

Based on the above structure, the size of the auxiliary connection portion F1 in the case where one auxiliary connection portion F1 patches the first line segment L11, the second line segment L12 and the third line segment L13 is greater than the size of the auxiliary connection portion F1 in the case where three different auxiliary connection portions F1 respectively patch the first line segment L11, the second line segment L12 and the third line segment L13. Therefore, in the case where the same auxiliary connection portion F1 is used to patch the first line segment L11, the second line segment L12 and the third line segment L13 at the same time, the size of the auxiliary connection portion F1 is large, which may be conducive to increasing a lapping area of the auxiliary connection portion F1 and the connection lead L1 and improving of the stability of the connection between the auxiliary connection portion F1 and the connection lead L1, and in turn ensures the yield of the connection lead.

In addition, the auxiliary connection portion F1 is arranged to overlap with the opening C in the first line segment L11, the opening C in the second line segment L12 and the opening C in the third line segment L13, which means that the auxiliary connection portion F1 includes a portion located on the first main surface S1, a portion located on the set side surface S31, and a portion located on the second main surface S2 that are connected. Since the portion located on the set side surface S31 may be connected to both the portion located on the first main surface S1 and the portion located on the second main surface S2, it may be conducive to reducing the probability of ends, which are respectively close to the first main surface S1 and the second main surface S2, of the auxiliary connection portion F1 on the set side surface S31 falling off from the substrate 01 (the third line segment L13).

In addition, in a case where at least one line segment of the connection lead L1 includes a plurality of openings, one auxiliary connection portion F1 may patch the openings, or a plurality of auxiliary connection portions F1 may patch the openings C one by one.

The above embodiments mainly introduces, with reference to the relevant drawings, the situations where at least one line segment in the connection lead L1 has at least one opening C. Next, the quantitative relationship between the connection leads L1 and the openings C will be introduced with reference to the relevant drawings.

In some embodiments, with continued reference to FIGS. 8 and 9, openings C in the connection lead L1 may be in one-to-one correspondence with auxiliary connection portions F1. That is, one auxiliary connection portion F1 patches one opening in the connection lead L.

That is, for each opening C found in a connection lead L in the light-emitting substrate 100, an auxiliary connection portion F1 is correspondingly provided, so that at least part of the auxiliary connection portion F1 is arranged in the opening C and the auxiliary connection portion F1 is arranged to be connected to the connection lead L1.

Based on this, the auxiliary connection portion F1 fills at least part of the opening C, so that the auxiliary connection portion F1 patches the opening C formed by the falling off of the connection lead L1. That is, the auxiliary connection portion F1 may replace the fallen-off part of the connection lead L1, so that the connection lead L1 can maintain normal circuit conduction. Therefore, the yield of the connection leads L1 may be improved.

In addition, since the openings C in the connection lead L1 may be in one-to-one correspondence with auxiliary connection portions F1, the shapes and sizes of the auxiliary connection portions F1 may be adjusted for different openings C, which may realize specified patching and facilitate saving resources.

FIG. 14 is a structural diagram of a light-emitting substrate, in accordance with some other embodiments. FIG. 14 shows a structure of a first line segment of a connection lead. As for the structures of other line segments of the connection lead which are similar to the structure of the first line segment, reference can be made to the introduction of the structure of the first line segment, and the structures of other line segments of the connection lead will also be described in detail below.

In some other embodiments, referring to FIG. 14, a connection lead L1 includes a plurality of openings C. One auxiliary connection portion F1 may be arranged corresponding to the plurality of openings C of one connection lead L1. That is, multiple parts of the auxiliary connection portion F1 may be located in the plurality of openings C of the one connection lead L1 at the same time, and the auxiliary connection portion F1 is connected to the connection lead L1.

Based on this, one auxiliary connection portion F1 fills the plurality of openings C formed in the connection lead L, so that the auxiliary connection portion F1 patches the plurality of openings C formed by the falling off of the connection lead L1. Therefore, the connection lead L1 can maintain normal circuit conduction. Thus, the yield of the connection leads L1 may be improved. In addition, a plurality of openings C in the same connection lead L1 may be patched by one auxiliary connection portion F1, which may be conducive to reducing the process accuracy of forming the auxiliary connection portion F1.

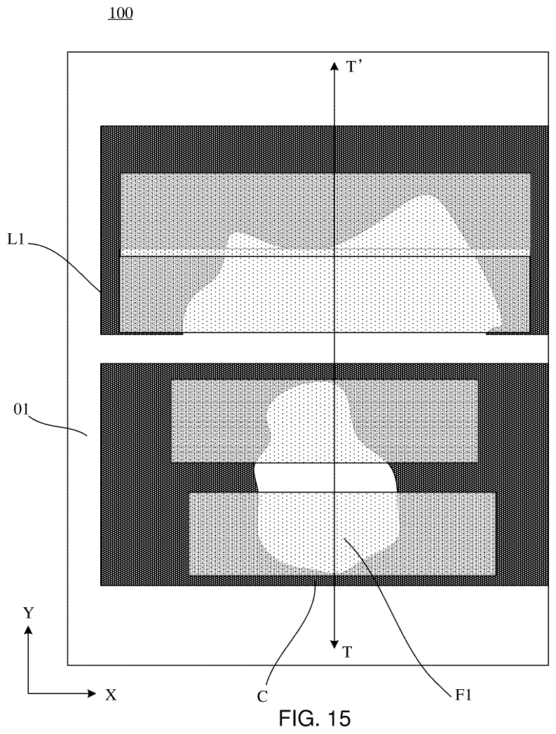

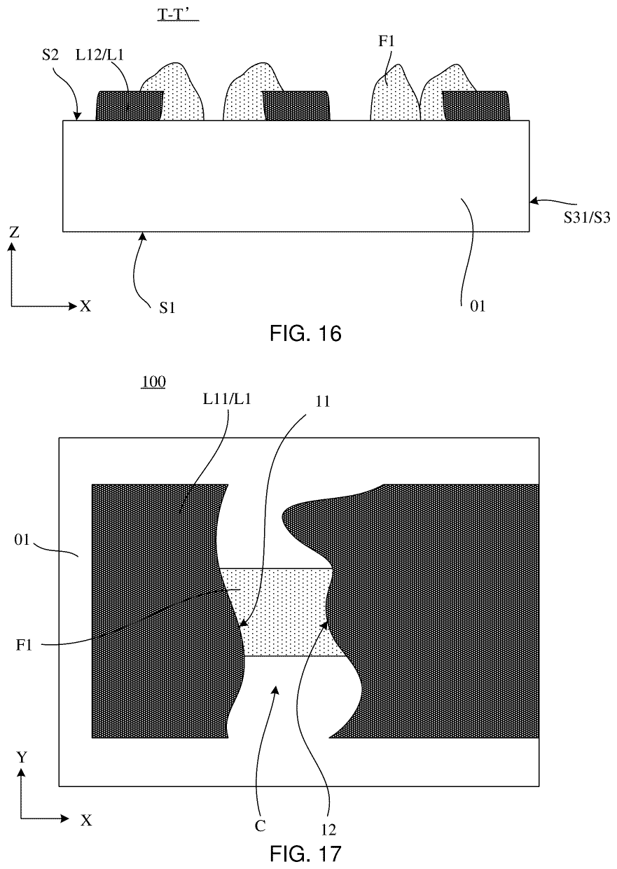

FIG. 15 is a structural diagram of a light-emitting substrate, in accordance with yet some other embodiments. FIG. 16 is a sectional view taken along the line T-T′ in FIG. 15. FIG. 15 shows a structure of a first line segment L11 of a connection lead. As for the structures of other line segments of the connection lead which are similar to the structure of the first line segment L11, reference can be made to the introduction of the structure of the first line segment, and the structures of other line segments of the connection lead will also be described in detail below.

In yet some other embodiments, referring to FIG. 15, at least two auxiliary connection portions F1 are at least partially arranged in the same opening C. Based on this, a plurality of auxiliary connection portions F1 may patch the same opening C, so that the connection lead L1 can maintain normal circuit conduction. In addition, since a plurality of auxiliary connection portions F1 patch the same opening C, the auxiliary connection portions F1 may occupy a large proportion of the opening C, and the auxiliary connection portions F1 will better patch the fallen-off part of the connection lead L1 to fill the opening C. This is beneficial to ensure that the connection lead L1 can maintain normal circuit conduction and improve the yield of the connection lead L1.

For example, the plurality of auxiliary connection portions F1 are arranged in a direction perpendicular to an extending direction of the connection lead L1, and the plurality of auxiliary connection portions F1 are all arranged in the opening C.

It will be noted that in the case where a plurality of auxiliary connection portions F1 are located in the same opening C, the connection relationship between the plurality of auxiliary connection portions F1 in the same opening C is as follows.

The first type is two auxiliary connection portions corresponding to the lower connection lead shown in FIG. 15 and two auxiliary connection portions F1 corresponding to the left connection lead L1 shown in FIG. 16. That is, the plurality of auxiliary connection portions F1 corresponding to the same opening C may be arranged at intervals.

The second type is two auxiliary connection portions corresponding to the upper connection lead shown in FIG. 15 and two auxiliary connection portions F1 corresponding to the right connection lead L1 shown in FIG. 16. That is, the plurality of auxiliary connection portions F1 corresponding to the same opening C may be electrically connected to each other.

No matter which of the above manners is adopted, as long as each auxiliary connection portion F1 is ensured to be in the opening C and connected to the connection lead L1 having the opening C, the auxiliary connection portion F1 patches and replaces a part of the opening C formed by the falling off of the connection lead L1, to ensure that the connection lead L1 can maintain normal circuit conduction. The embodiments of the present disclosure are not limited thereto.

The following description will be made by taking one auxiliary connection portion F1 patching one opening C as an example.

The above embodiments describe the positional relationship and the quantitative relationship between the connection lead L1 and the auxiliary connection portion F1 with reference to the relevant drawings. The following description will introduce parameters of the auxiliary connection portion F1 (e.g., sheet resistance, thickness, length, etc. of the auxiliary connection portion F1) with reference to the relevant drawings.

In some embodiments, with continued reference to FIGS. 8 and 9, a sheet resistance of the auxiliary connection portion F1 is less than or equal to a sheet resistance of the connection lead L1.

That is, the auxiliary connection portion F1, whose sheet resistance is less than or equal to the sheet resistance of the connection lead L1, is selected to replace the fallen-off portion of the connection lead L1. This may avoid a problem that the auxiliary connection portion F1 generates large impedance during the operation of the light-emitting substrate 100 due to larger sheet resistance of the auxiliary connection portion F1. Therefore, the influence of the auxiliary connection portion F1 on the electrical properties of the connection lead L1 may be ameliorated.

In addition, the auxiliary connection portion F1 needs to be in contact with the connection lead L1 having the opening C, so that the auxiliary connection portion F1 is electrically connected to the connection lead L1. Therefore, the connection lead L1 can maintain normal circuit conduction by using the auxiliary connection portion F1.

Based on this, by selecting the auxiliary connection portion F1 whose square resistance is less than or equal to the square resistance of the connection lead L1, it may also be conducive to reducing the contact resistance between the auxiliary connection portion F1 and the connection lead L1. Therefore, it may be possible to mitigate the attenuation of the signal transmitted by the connection lead L1 caused by the contact resistance between the auxiliary connection portion F1 and the connection lead L1, and it may be conducive to improving the display quality of the light-emitting substrate 100.

In some embodiments, with continued reference to FIGS. 8 and 9, a material of the auxiliary connection portion F1 includes a conductive adhesive. At least part of the conductive adhesive is arranged in the opening C, and the conductive adhesive is used to be connected to the connection lead L1 where the opening C is located.

In an aspect, the conductive adhesive has conductivity, which may realize electrical connection between the auxiliary connection portion F1 (the conductive adhesive) and the connection lead L1, so that the connection lead L1 can maintain normal circuit conduction. In another aspect, the conductive adhesive has stickiness, which may ensure fixed connection between the auxiliary connection portion F1 (the conductive adhesive) and the connection lead L1, which avoids a problem of the low yield of the connection lead L1 caused by the conductive adhesive being detached from the connection lead L1.

In some examples, the material of the conductive adhesive may include conductive silver paste or conductive gold paste. The conductive silver paste or the conductive gold paste has the advantages of low curing temperature, high adhesion strength and stable electrical properties. The conductive silver paste or the conductive gold paste is arranged in the opening C, and the conductive adhesive is used to be connected to the connection lead L1 where the opening C is located. The electrical performance of the connection lead L1 patched by the auxiliary connection portion F1 (conductive silver paste or conductive gold paste) may be guaranteed, and the risk of the auxiliary connection portion F1 (conductive silver paste or conductive gold paste) being detached from the connection lead L1 may be reduced.

In some examples, the conductive adhesive may include an adhesive and metal balls located in the adhesive. In this way, the electrical performance of the connection lead L1 patched by the auxiliary connection portion F1 (conductive adhesive) may be guaranteed, and the risk of the auxiliary connection portion F1 (conductive adhesive) being detached from the connection lead L1 may be reduced.

For example, the adhesive may be made of ultraviolet rays (UV) glue or thermosetting adhesive. However, the embodiments of the present disclosure are not limited thereto.

For example, the metal balls may be made of inert metal, such as silver and gold. However, the embodiments of the present disclosure are not limited thereto.

In some embodiments, with continued reference to FIGS. 8 and 9, in the thickness direction Z of the substrate 01, a thickness of the auxiliary connection portion F1 is in a range of 5 μm to 20 μm.

In the case where the thickness of the auxiliary connection portion F1 is equal to or approaches 5 μm, the thickness of the auxiliary connection portion F1 may be small, so that the auxiliary connection portion F1 may be attached to the connection lead L1 and the substrate 01 more closely, and the risk of the auxiliary connection portion F1 being detached from the connection lead L1 and the substrate 01 is reduced. In addition, in the case where the thickness of the auxiliary connection portion F1 is equal to or approaches 5 μm, it may avoid a problem that the auxiliary connection portion F1 has high resistance due to the small thickness of the auxiliary connection portion F1. Furthermore, it may be conducive to reducing the attenuation of the signal transmitted by the connection lead that is patched by the auxiliary connection portion F1 caused by the auxiliary connection portion F1, and may be conducive to improving the display quality of the light-emitting substrate 100.

In the case where the thickness of the auxiliary connection portion F1 is equal to or approaches 20 μm, the thickness of the auxiliary connection portion F1 is large, so that the resistance of the auxiliary connection portion F1 may be low. Therefore, it may be conducive to reducing the attenuation of the signal transmitted by the connection lead that is patched by the auxiliary connection portion F1 caused by the resistance of the auxiliary connection portion F1, and may be conducive to improving the display quality of the light-emitting substrate 100. In addition, in the case where the thickness of the auxiliary connection portion F1 is equal to or approaches 20 μm, it may be possible to avoid that the risk of the auxiliary connection portion F1 being detached from the substrate 01 and the connection lead L1 is increased due to the excessive thickness of the auxiliary connection portion F1.

In some examples, the thickness of the auxiliary connection portion F1 is in a range of 10 μm to 15 μm.

In the case where the thickness of the auxiliary connection portion F1 is equal to or approaches 10 μm, the auxiliary connection portion F1 may be attached to the connection lead L1 and the substrate 01 more closely, and the risk of the auxiliary connection portion F1 being detached from the connection lead L1 and the substrate 01 is reduced; in addition, a high resistance of the auxiliary connection portion F1 may be avoided, which may be conducive to reducing the attenuation of the signal transmitted by the connection lead that is patched by the auxiliary connection portion F1 caused by the auxiliary connection portion F1, and may be conducive to improving the display quality of the light-emitting substrate 100.

In the case where the thickness of the auxiliary connection portion F1 is equal to or approaches 15 μm, the resistance of the auxiliary connection portion F1 may be small, which may reduce the attenuation of the signal transmitted by the connection lead that is patched by the auxiliary connection portion F1 caused by the auxiliary connection portion F1; and it may also be possible to avoid that the risk of the auxiliary connection portion F1 being detached from the substrate 01 and the connection lead L1 is increased due to the excessive thickness of the auxiliary connection portion F1.

For example, the thickness of the auxiliary connection portion F1 is approximately any one of 5 μm, 8 μm, 10 μm, 12 μm, 15 μm, 18 μm, or 20 μm. However, the embodiments of the present disclosure are not limited thereto.

It will be noted that considering an example in which the thickness of the auxiliary connection portion F1 is approximately 10 μm for introduction, due to certain uncontrollable errors (such as manufacturing process errors, equipment accuracy, measurement errors, etc.), in a case where an error of the thickness of the auxiliary connection portion F1 fluctuates within a range of 10%×10 μm, it will also be considered that the thickness of the auxiliary connection portion F1 satisfies a condition of being equal to 10 μm.

In addition, in some other examples, due to certain uncontrollable errors (such as manufacturing process errors, equipment accuracy, measurement errors, etc.), in a case where an error of the thickness of the auxiliary connection portion F1 fluctuates within a range of 5%×10 μm, it will also be considered that the thickness of the auxiliary connection portion F1 satisfies a condition of being equal to 10 μm.

The material and thickness of the auxiliary connection portion F1 are introduced above with reference to the relevant drawings. The following description will introduce, with reference to the relevant drawings, the length and width of the auxiliary connection portion F1 and how to arrange the auxiliary connection portion F1 so that the auxiliary connection portion F1 is connected to the connection lead L1.

FIG. 17 is a structural diagram of a light-emitting substrate, in accordance with yet some other embodiments. FIG. 17 shows a first line segment L11 of a connection lead L1 on a light-emitting substrate 100.

First, referring to FIG. 17, the first arrangement described above will be introduced, where the entire auxiliary connection portion F1 is arranged in the opening C.

In a case where the connection lead L1 is divided into two portions due to the opening C formed by a part of the connection lead L1 falling off, a first edge 11 and a second edge 12 corresponding to the two portions will be formed in the connection lead L1. The first edge 11, the second edge 12, and a region between the first edge 11 and the second edge 12 constitute the opening C.

Based on this, in the case where the entire auxiliary connection portion F1 is arranged in the opening C, an end of the auxiliary connection portion F1 may abut against the first edge 11, and another end of the auxiliary connection portion F1 may abut against the second edge 12. Thus, the auxiliary connection portion F1 abuts against the connection lead L1 in the opening C, so that the auxiliary connection portion F1 patches the fallen-off part of the connection lead L1, and the connection lead L1 can maintain normal circuit conduction using the auxiliary connection portion F1.

In some examples, FIG. 17 only illustrates that an end of the auxiliary connection portion F1 abuts against a part of the first edge 11, and another end of the auxiliary connection portion F1 abuts against a part of the second edge 12. That is, the auxiliary connection portion F1 can fill a part of the opening C. However, the present disclosure is not limited thereto, as long as the connection lead L1 can maintain normal circuit conduction using the auxiliary connection portion F1.

It will be understood that, in some other examples, an end of the auxiliary connection portion F1 may abut against the entire first edge 11, and another end of the auxiliary connection portion F1 may abut against the entire second edge 12. That is, the auxiliary connection portion F1 can fill the entire opening C, so that the auxiliary connection portion F1 can replace and patch the entire fallen-off part of the connection lead L1. Therefore, the connection lead L1 can maintain normal circuit conduction using the auxiliary connection portion F1, which improves the yield of the connection lead L1.

In a case where the opening C formed by a part of the connection lead L1 falling off does not cause the connection lead L1 to be divided into two portions, an edge will be formed in the connection lead L1 due to the fallen-off part. The edge is recessed inwards relative to the original structure of the connection lead L1, so as to form the opening C.

Based on this, the auxiliary connection portion F1 can be arranged in the opening C, and abuts against a part of the edge or abuts against the entire edge. Therefore, the connection lead L1 can maintain normal circuit conduction using the auxiliary connection portion F1.

Secondly, the second arrangement described above will be introduced, where a part of the auxiliary connection portion F1 is arranged in the opening C.

In some embodiments, referring to FIGS. 8 and 9, the auxiliary connection portion F1 includes a main body portion F11 and at least one lapping portion F12 connected to the main body portion F11. The main body portion F11 is located in the opening C. The lapping portion F12 is located on a side of the connection lead L1 away from the substrate 01, and the lapping portion F12 is in contact with the connection lead L1.

In this way, a part of the auxiliary connection portion F1 (the main body portion F11) is arranged in the opening C, and another part of the auxiliary connection portion F1 (the lapping portion F12) is arranged on the side of the connection lead L1 away from the substrate 01. The auxiliary connection portion F1 (the lapping portion F12) is in direct contact with the connection lead L1, thereby realizing electrical connection between the auxiliary connection portion F1 and the connection lead L1.

Moreover, since the lapping portion F12 exists, it may be conducive to increasing the contact area between the auxiliary connection portion F1 and the connection lead L1, improving the stability between the auxiliary connection portion F1 and the connection lead L1, and preventing the auxiliary connection portion F1 from being detached from the connection lead L1.

A quantity of lapping portions F12 in the auxiliary connection portion F1 may be set based on the position of the opening C in the connection lead L1. Therefore, the auxiliary connection portion F1 patches the connection lead L1, and the electrical performance of the connection lead L1 is guaranteed.

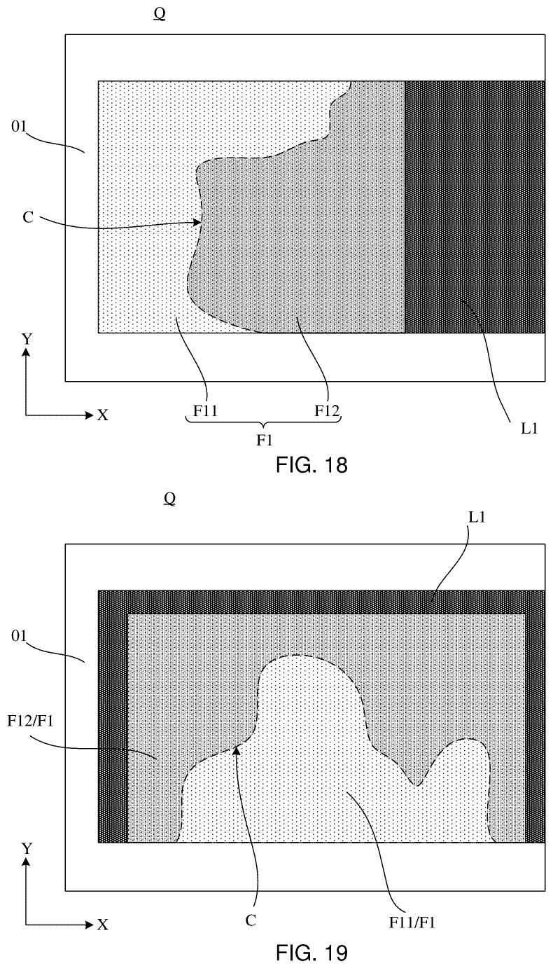

FIG. 18 is a structural diagram of a light-emitting substrate, in accordance with yet some other embodiments. FIG. 19 is a structural diagram of a light-emitting substrate, in accordance with yet some other embodiments.

In some examples, referring to FIGS. 18 and 19, the opening C is located at an end of the connection lead L1, that is, the opening C does not cause the connection lead L1 to be divided into a plurality of line sections. The auxiliary connection portion F1 may include a main body portion F11 and a lapping portion F12 connected to the main body portion F11. The main body portion F11 is disposed in the opening C, and the lapping portion F12 is disposed on the connection lead L1. Therefore, the lapping portion F12 is connected to the connection lead L1 having the opening C, and the electrical connection between the auxiliary connection portion F1 and the connection lead L1 is realized.

Based on this, the auxiliary connection portion F1 may patch the opening C formed by a part of the connection lead L1 falling off, so that the connection lead L1 can maintain normal circuit conduction. Therefore, it may be conducive to improving the yield of the connection lead L1, and improving the display quality of the light-emitting substrate 100.

It will be noted that the “end” of the connection lead L refers to an edge position of the connection lead L1. The opening C at this position does not directly cause the connection lead L1 to be divided into a plurality of line sections. The “end” may be an edge position of the connection lead L1 in a length direction of the connection lead L1, or an edge position of the connection lead L1 in a width direction of the connection lead L1, which is not limited in the embodiments of the present disclosure.

In some other examples, the opening C is located inside the connection lead L1, and the opening C divides the connection lead L1 into a plurality of portions. Referring to FIGS. 8 and 9, the connection lead L1 having one opening C inside is taken as an example for description. In this case, the connection lead L1 having the opening C is divided into two portions.

In this case, the auxiliary connection portion F1 may include a main body portion F11 and two lapping portions F12 connected to the main body portion F11. The main body portion F11 is located between the two lapping portions F12.

Based on this, the auxiliary connection portion F1 may be connected to one portion of the connection lead L1 using one lapping portion F12, and the auxiliary connection portion F1 may be connected to another portion of the connection lead L1 using another lapping portion F12. Based on this, the auxiliary connection portion F1 may patch the connection lead L1 to ensure that the connection lead L1 can maintain normal circuit conduction.

In a case where the opening C penetrates through the connection lead L1 in the length direction or width direction of the connection lead L1, the connection lead L1 is divided into a plurality of line sections. For example, the connection lead L1 having one opening C is divided into two line sections. For example, the connection lead L1 having two openings C is divided into three line sections.

Based on this, the auxiliary connection portion F1 may be connected to one line section of the connection lead L1 using one lapping portion F12, and the auxiliary connection portion F1 may be connected to another line section of the connection lead L1 using another lapping portion F12. Furthermore, two disconnected line sections may be electrically connected through the auxiliary connection portion F1, so that the two line sections and the auxiliary connection portion F1 constitute a connection lead L1 that is patched, ensuring that the connection lead L1 can maintain normal circuit conduction.

In some embodiments, with continued reference to FIGS. 8 and 9, in a direction pointing from the main body portion F11 to the lapping portion F12, a width of the lapping portion F12 is greater than or equal to 10 μm.

In this way, the auxiliary connection portion F1 extends from the inside of the opening C outwardly to the connection lead L1, and is lapped on the connection lead L1. In addition, a width of a lapping region of the auxiliary connection portion F1 and the connection lead L1 is set to be greater than or equal to 10 μm, which may ensure that the auxiliary connection portion F1 is sufficiently in contact with the connection lead L1, thereby improving the stability of the fixed connection between the auxiliary connection portion F1 and the connection lead L1. This may help avoid a problem of the low yield of the connection lead L1 caused by the conductive adhesive being detached from the connection lead L1.

In the case where the width of the lapping portion F12 in the direction pointing from the main body portion F11 to the lapping portion F12 is equal to or approaches 10 μm, the width of the lapping region of the auxiliary connection portion F1 and the connection lead L1 may be ensured to be large, which may ensure that the auxiliary connection portion F1 is sufficiently in contact with the connection lead L1, thereby improving the stability of the fixed connection between the auxiliary connection portion F1 and the connection lead L1.

It will be noted that the opening C in the connection lead L1 is formed because a part of the connection lead L1 falls off from the substrate 01. Therefore, the shape of the opening C cannot be guaranteed. The opening C may be of a regular shape, such as circle, square, polygon, etc. Alternatively, the opening C may be of an irregular shape.

Based on this, the “width of the lapping portion F12” described above can be understood as a minimum distance between an orthogonal projection, on the substrate 01, of an edge of the lapping portion F12 away from the main body portion F11 and an orthogonal projection, on the substrate 01, of a border of the opening C.

In some examples, in the direction pointing from the main body portion F11 to the lapping portion F12, the width of the lapping portion F12 is greater than or equal to 15 μm.

In the case where the width of the lapping portion F12 in the direction pointing from the main body portion F11 to the lapping portion F12 is equal to or approaches 15 μm, it may ensure that the auxiliary connection portion F1 is sufficiently in contact with the connection lead L1, thereby improving the stability of the fixed connection between the auxiliary connection portion F1 and the connection lead L1.

For example, in the direction pointing from the main body portion F11 to the lapping portion F12, the width of the lapping portion F12 is approximately any one of 10 μm, 12 μm, 15 μm, 20 μm, 25 μm or 30 μm.

It will be noted that considering an example in which the width of the lapping portion F12 is approximately 10 μm for introduction, due to certain uncontrollable errors (such as manufacturing process errors, equipment accuracy, measurement errors, etc.), in a case where an error of the width of the lapping portion F12 fluctuates within a range of 10%×10 μm, it will also be considered that the width of the lapping portion F12 satisfies a condition of being equal to 10 μm.

In addition, in some other examples, due to certain uncontrollable errors (such as manufacturing process errors, equipment accuracy, measurement errors, etc.), in a case where an error of the width of the lapping portion F12 fluctuates within a range of 5%×10 μm, it will also be considered that the width of the lapping portion F12 satisfies a condition of being equal to 10 μm.

The minimum size of the lapping region of the auxiliary connection portion F1 and the connection lead L1 is described above with reference to the drawings. The maximum size of the lapping region of the auxiliary connection portion F1 and the connection lead L1 will be described in detail with reference to the drawings.

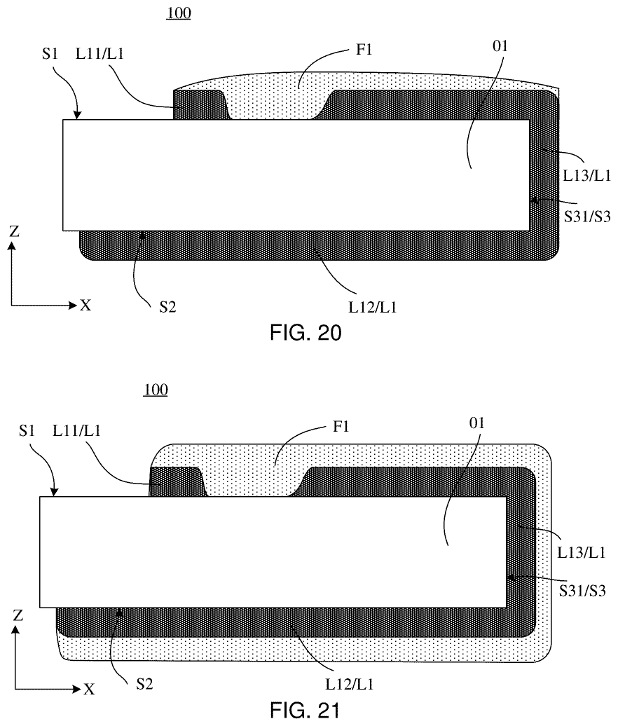

FIG. 20 is a sectional view of a light-emitting substrate, in accordance with some other embodiments.

In some embodiments, referring to FIG. 20, when any of the three line segments (the first line segment L11, the second line segment L12 and the third line segment L13) in the connection lead L1 has an opening C, in an extending direction of the connection lead L1, the length of the auxiliary connection portion F1 is less than or equal to a length of a line segment having an opening C.

Based on this, the auxiliary connection portion F1 can be used to patch the line segment having the opening C to improve the yield of the connection lead L1. In addition, by setting the length of the auxiliary connection portion F1 to be less than or equal to the length of the line segment having the opening C, a lapping width of the auxiliary connection portion F1 and the line segment having the opening C may be guaranteed, which may ensure that the auxiliary connection portion F1 is sufficiently in contact with the line segment having the opening C, so as to improve the stability of the fixed connection between the auxiliary connection portion F1 and the connection lead L1.

Moreover, in the length direction of the connection lead L1, the length of the auxiliary connection portion F1 is less than or equal to the length of the line segment having the opening C, which may avoid that the excessive length of the auxiliary connection portion F1 causes the auxiliary connection portion F1 in contact with other conductive components in the light-emitting substrate 100 and causes short circuit, and may also facilitate saving resources.

In the case where in the length direction of the connection lead L1, the length of the auxiliary connection portion F1 is equal to or approaches the length of the line segment having the opening C, the lapping width of the auxiliary connection portion F1 and the line segment having the opening C may be large, so that the auxiliary connection portion F1 may sufficiently patch the line segment having the opening C to ensure that the line segment can maintain normal circuit conduction. In addition, it may be conducive to improving the stability of the connection between the auxiliary connection portion F1 and the connection lead L1.

Since the three line segments of the connection lead L1 are respectively formed on different surfaces of the substrate 01, extending directions of the three line segments are different. The above-mentioned “extending direction” refers to the extending direction of the line segment having the opening C.

In some examples, in a case where the opening C is formed in the first line segment L11 of the connection lead L1, in the extending direction of the first line segment L11, the length of the auxiliary connection portion F1 is less than or equal to the length of the first line segment L11 having the opening C.

In some other examples, in a case where the opening C is formed in the second line segment L12 of the connection lead L1, in the extending direction of the second line segment L12, the length of the auxiliary connection portion F1 is less than or equal to the length of the second line segment L12 having the opening C.

In yet some other examples, in a case where the opening C is formed in the third line segment L13 of the connection lead L1, in the extending direction of the third line segment L13, the length of the auxiliary connection portion F1 is less than or equal to the length of the third line segment L13 having the opening C.

It will be noted that in a case where the opening C in the connection lead L1 is located at a position of a junction of the first line segment L11 and the third line segment L13, there are the following situations:

In the first situation, the opening C may belong to the first line segment L11, the length of the auxiliary connection portion F1 is less than or equal to the length of the first line segment L11, and the auxiliary connection portion F1 may be connected to both the first line segment L11 and the third line segment L13.

In the second situation, the opening C may belong to the third line segment L13, the length of the auxiliary connection portion F1 is less than or equal to the length of the third line segment L13, and the auxiliary connection portion F1 may be connected to both the first line segment L11 and the third line segment L13.

In the third situation, the opening C may be divided into two parts, a part of the opening C close to the first line segment L11 belongs to the first line segment L11, and a part of the opening C close to the third line segment L13 belongs to the third line segment L13. In this case, the length of the opening C may be less than or equal to a sum of the length of the first line segment L11 and the length of the third line segment L13, and the auxiliary connection portion F1 may be connected to both the first line segment L11 and the third line segment L13.

In addition, for the case where the opening C in the connection lead L1 is located at a position of a junction of the second line segment L12 and the third line segment L13, it is similar to the above-mentioned case where the opening C in the connection lead L1 is located at the position of the junction of the first line segment L11 and the third line segment L13, and details will not be repeated here.

In some examples, in the extending direction of the connection lead L1 (the extending direction of the line segment having the opening C), the length of the auxiliary connection portion F1 is equal to the length of the line segment having the opening C.

Based on this, a border, in the extending direction of the connection lead L1, of an orthogonal projection of the auxiliary connection portion F1 on the substrate 01 substantially coincides with a border, in the extending direction of the connection lead L1, of an orthogonal projection of the line segment having the opening C on the substrate 01.

In this way, in the extending direction of the connection lead L1 (the extending direction of the line segment having the opening C), two ends of the auxiliary connection portion F1 are respectively aligned with two ends of the line segment. The lapping width of the auxiliary connection portion F1 and the line segment having the opening C may be large, so that the auxiliary connection portion F1 may sufficiently patch the line segment having the opening C to ensure that the line segment can maintain normal circuit conduction. In addition, it may be conducive to improving the stability of the connection between the auxiliary connection portion F1 and the connection lead L1.

It will be noted that, “coincide substantially” includes absolute coincidence and approximate coincidence. That is, a floating range of a gap between a border of the orthogonal projection of the auxiliary connection portion F1 on the substrate 01 and a border of the orthogonal projection of the line segment having the opening C on the substrate 01 does not exceed an error threshold; and it may also be considered that edges of the auxiliary connection portion F1 and the line segment are relatively “coincident”. The error threshold may be less than 10% of the length of the line segment having the opening C.

In addition, in the case where there are a plurality of openings C in the same line segment, by setting the length of the auxiliary connection portion F1 to be less than or equal to the length of the line segment having the openings C, the length of the auxiliary connection portion F1 may be large, so that the orthogonal projection of the auxiliary connection portion F1 on the substrate 01 can overlap with orthogonal projections of the plurality of openings C on the substrate 01 at the same time. Thus, the auxiliary connection portion F1 can be used to patch the plurality of openings C in the line segment at the same time. Based on this, there is no need to provide an auxiliary connection portion F1 for each opening C, which may help simplify the process.

FIG. 20 illustrates an example in which the first line segment L11 of the connection lead L1 has one opening C. However, the embodiments of the present disclosure are not limited thereto.

FIG. 21 is a sectional view of a light-emitting substrate, in accordance with yet some other embodiments.

In some embodiments, referring to FIG. 21, in the extending direction of the connection lead L1, the length of the auxiliary connection portion F1 is less than or equal to the length of the connection lead L1 having the opening C.

Based on this, the auxiliary connection portion F1 can be used to patch the connection lead L1 having the opening C, so as to improve the yield of the connection lead L1. Furthermore, the structure of the auxiliary connection portion F1 is similar to the structure of the connection lead L1, and the extending direction of the auxiliary connection portion F1 is arranged to be parallel to the extending direction of the connection lead L1. Based on this, setting the length of the auxiliary connection portion F1 to be less than or equal to the length of the connection lead L1 having the opening C, the lapping size of the auxiliary connection portion F1 and the connection lead L1 having the opening C may be guaranteed, which may ensure that the auxiliary connection portion F1 is sufficiently in contact with the connection lead L1 having the opening C, so as to improve the stability of the fixed connection between the auxiliary connection portion F1 and the connection lead L1.

In addition, in the extending direction of the connection lead L1, the length of the auxiliary connection portion F1 is less than or equal to the length of the connection lead L1 having the opening C, which may avoid that the excessive length of the auxiliary connection portion F1 causes the auxiliary connection portion F1 in contact with other conductive components in the light-emitting substrate 100 and causes short circuit, and may also facilitate saving resources.

In the case where in the extending direction of the connection lead L1, the length of the auxiliary connection portion F1 is equal to or approaches the length of the connection lead L1 having the opening C, the lapping area of the auxiliary connection portion F1 and the line segment having the opening C may be large, and the auxiliary connection portion F1 may sufficiently patch the connection lead L1 having the opening C, so as to ensure that the connection lead L1 can maintain normal circuit conduction. In addition, it may be conducive to improving the stability of the connection between the auxiliary connection portion F1 and the connection lead L1.

In some examples, with continued reference to FIG. 21, in the extending direction of the connection lead L1, the length of the auxiliary connection portion F1 is approximately equal to the length of the connection lead L1 having the opening C.

In this case, the structure of the auxiliary connection portion F1 is similar to the structure of the connection lead L1, and the auxiliary connection portion F1 extends from the first main surface S1 to the second main surface S2. That is, the auxiliary connection portion F1 includes: a first auxiliary connection sub-portion corresponding to the first line segment L11, a third auxiliary connection sub-portion corresponding to the third line segment L13, and a second auxiliary connection sub-portion corresponding to the second line segment L12; and the third auxiliary connection sub-portion is connected to the first auxiliary connection sub-portion and the second auxiliary connection sub-portion to constitute the auxiliary connection portion F1.

Based on the above structure, in the extending direction of the connection lead L1, the length of the auxiliary connection portion F1 is approximately equal to the length of the connection lead L1 having the opening C. It will be understood that, in the extending direction of the first line segment L11, a length of the first auxiliary connection sub-portion is approximately equal to the length of the first line segment L11; in the extending direction of the third line segment L13, a length of the third auxiliary connection sub-portion is approximately equal to the length of the third line segment L13; and in the extending direction of the second line segment L12, a length of the second auxiliary connection sub-portion is approximately equal to the length of the second line segment L12. Based on this, in the extending direction of the connection lead L1, the length of the auxiliary connection portion F1 is approximately equal to the length of the connection lead L1 having the opening C.

Furthermore, the lapping width of the auxiliary connection portion F1 and the connection lead L1 having the opening C may be large, and the auxiliary connection portion F1 may sufficiently patch the connection lead L1 having the opening C, so as to ensure that the connection lead L1 can maintain normal circuit conduction. In addition, it may be conducive to improving the stability of the connection between the auxiliary connection portion F1 and the connection lead L1.

In addition, in the case where there are a plurality of openings C in the same connection lead L1, for example, if defective openings are formed in different line segments of the same connection lead L1, the length of the auxiliary connection portion F1 may be set to be less than or equal to the length of the connection lead L1 having the opening C, so that the length of the auxiliary connection portion F1 is large. Therefore, the orthogonal projection of the auxiliary connection portion F1 on the substrate 01 can overlap with orthogonal projections of the plurality of openings C on the substrate 01 at the same time. Thus, the auxiliary connection portion F1 can be used to patch the plurality of openings C in the connection lead L1 at the same time. Based on this, there is no need to provide an auxiliary connection portion F1 for each opening C, which may help simplify the process.

The above description mainly introduces the length of the auxiliary connection portion F1. The width of the auxiliary connection portion F1 will be described below with reference to the drawings.

In some embodiments, referring to FIGS. 8 and 9, in the width direction of the connection lead L1, a ratio of the width of the at least part of the auxiliary connection portion F1 located in the opening C to the width of the opening C is greater than or equal to 50%.

In a case where in the width direction of the connection lead L1, the ratio of the width of the at least part of the auxiliary connection portion F1 located in the opening C to the width of the opening C is equal to or approaches 50%, the auxiliary connection portion F1 may occupy a large proportion of the opening C, so that the auxiliary connection portion F1 will patch the fallen-off part of the connection lead L1 to fill the opening C. This is beneficial to ensure that the connection lead L1 can maintain normal circuit conduction and improve the yield of the connection lead L1.

In some examples, the width direction of the connection lead L1 is approximately perpendicular to the extending direction of the connection lead L1. In this case, an included angle between the width direction of the connection lead L1 and the extending direction of the connection lead L1 is approximately equal to 90°. For example, the included angle between the width direction of the connection lead L1 and the extending direction of the connection lead L1 may be 85°, 90° or 95°.

In some examples, in the width direction of the connection lead L1, the ratio of the width of the at least part of the auxiliary connection portion F1 located in the opening C to the width of the opening C is greater than or equal to 80%.

In the case where in the width direction of the connection lead L1, the ratio of the width of the at least part of the auxiliary connection portion F1 located in the opening C to the width of the opening C is equal to or approaches 80%, the auxiliary connection portion F1 may occupy a larger proportion of the opening C, and the auxiliary connection portion F1 will better patch the fallen-off part of the connection lead L1 to fill the opening C. This is beneficial to ensure that the connection lead L1 can maintain normal circuit conduction and improve the yield of the connection lead L1.

In some examples, in the width direction of the connection lead L1, the ratio of the width of the at least part of the auxiliary connection portion F1 located in the opening C to the width of the opening C is greater than or equal to 100%. That is, the width of the at least part of the auxiliary connection portion F1 located in the opening C is approximately equal to the width of the opening C.

In this way, the auxiliary connection portion F1 can be used to fill the opening C, which is beneficial to ensure that the connection lead L1 can maintain normal circuit conduction and improve the yield of the connection lead L1.

For example, in the width direction of the connection lead L1, the ratio of the width of the at least part of the auxiliary connection portion F1 located in the opening C to the width of the opening C is approximately any one of 50%, 60%, 70%, 80%, 90% or 100%. However, the embodiments of the present disclosure are not limited thereto.

It will be noted that, considering an example in which in the width direction of the connection lead L1, the ratio of the width of the at least part of the auxiliary connection portion F1 located in the opening C to the width of the opening C is approximately 50% for introduction, due to certain uncontrollable errors (such as manufacturing process errors, equipment accuracy, measurement errors, etc.), in a case where an error of the ratio fluctuates within a range of 10%×50%, it will also be considered that the ratio of the width of the at least part of the auxiliary connection portion F1 located in the opening C to the width of the opening C is approximately 50%.

In addition, in some other examples, due to certain uncontrollable errors (such as manufacturing process errors, equipment accuracy, measurement errors, etc.), in a case where an error of the ratio fluctuates within a range of 5%×50%, it will also be considered that the ratio of the width of the at least part of the auxiliary connection portion F1 located in the opening C to the width of the opening C is approximately 50%.

In some embodiments, referring to FIGS. 8 and 9, in the width direction of the connection lead L1, the width of the auxiliary connection portion F1 is in a range of 50 μm to 100 μm.

In the case where the width of the auxiliary connection portion F1 in the width direction of the connection lead L1 is equal to or approaches 50 μm, the width of the auxiliary connection portion F1 may be large, and the auxiliary connection portion F1 may occupy a large proportion of the opening C, so that the auxiliary connection portion F1 will better patch the fallen-off part of the connection lead L1 to fill the opening C, which is beneficial to ensure that the connection lead L1 can maintain normal circuit conduction and improve the yield of the connection lead L1. In addition, it may also help avoid that the excessive width of the auxiliary connection portion F1 causes short circuit between the auxiliary connection portion F1 and other connection lead L1 adjacent to the connection lead L1 that is patched by the auxiliary connection portion F1.

In the case where the width of the auxiliary connection portion F1 in the width direction of the connection lead L1 is equal to or approaches 100 μm, the opening C may be better filled, so that the connection lead L1 is patched and the yield of the connection lead L1 is improved. In addition, the resistance of the auxiliary connection portion F1 may be low, which may ameliorate the loss of the signal transmitted by the patched connection lead L1 caused by the resistance of the auxiliary connection portion F1.

In some examples, referring to FIGS. 8 and 9, in the width direction of the connection lead L1, the width of the auxiliary connection portion F1 is in a range of 60 μm to 80 μm.

In the case where the width of the auxiliary connection portion F1 in the width direction of the connection lead L1 is equal to or approaches 60μm, the auxiliary connection portion F1 may occupy a large proportion of the opening C, so that the connection lead L1 is patched and the yield of the connection lead L1 is improved. In addition, it may also avoid the short circuit between the auxiliary connection portion F1 and other connection lead L1 adjacent to the connection lead L1 that is patched by the auxiliary connection portion F1.

In the case where the width of the auxiliary connection portion F1 in the width direction of the connection lead L1 is equal to or approaches 80 μm, the auxiliary connection portion F1 may better fill the opening C, and the yield of the connection lead L1 is improved. In addition, the resistance of the auxiliary connection portion F1 may be low, which ameliorates the loss of the signal transmitted by the patched connection lead L1 caused by the resistance of the auxiliary connection portion F1.

For example, in the width direction of the connection lead L1, the width of the auxiliary connection portion F1 is approximately any one of 50 μm, 60 μm, 70 μm, 80 μm, 90 μm, or 100 μm. However, the embodiments of the present disclosure are not limited thereto.

It will be noted that, considering an example in which the width of the auxiliary connection portion F1 in the width direction of the connection lead L1 is approximately 50 μm for introduction, due to certain uncontrollable errors (such as manufacturing process errors, equipment accuracy, measurement errors, etc.), in a case where an error of the width of the auxiliary connection portion F1 fluctuates within a range of 10%×50 μm, it will also be considered that the width of the auxiliary connection portion F1 satisfies a condition of being equal to 50 μm.

In addition, in some other examples, due to certain uncontrollable errors (such as manufacturing process errors, equipment accuracy, measurement errors, etc.), in a case where an error of the width of the auxiliary connection portion F1 fluctuates within a range of 5%×50 μm, it will also be considered that the width of the auxiliary connection portion F1 satisfies a condition of being equal to 50 μm.

In some embodiments, as shown in FIG. 8, a ratio of an overlapping area of the orthogonal projection of the auxiliary connection portion F1 on the substrate 01 and the orthogonal projection of the opening C on the substrate 01 to an area of the orthogonal projection of the opening C on the substrate 01 is greater than or equal to 50%.

In the case where the auxiliary connection portion F1 is arranged in the opening C and the auxiliary connection portion F1 is connected to the connection lead L1 having the opening C, when the ratio of the overlapping area of the orthogonal projection of the auxiliary connection portion F1 on the substrate 01 and the orthogonal projection of the opening C on the substrate 01 to the area of the orthogonal projection of the opening C on the substrate 01 is equal to or approaches 50%, the auxiliary connection portion F1 may replace more than 50% of the fallen-off part of the connection lead L1, which may patch the connection lead having the opening C well. Therefore, the connection lead L1 may have good electrical performance, which ensures that the connection lead L1 can maintain normal circuit conduction and in turn improves the yield of the connection lead L1.

In some examples, the ratio of the overlapping area of the orthogonal projection of the auxiliary connection portion F1 on the substrate 01 and the orthogonal projection of the opening C on the substrate 01 to the area of the orthogonal projection of the opening C on the substrate 01 is approximately 50%.

In the case where the auxiliary connection portion F1 is arranged in the opening C and the auxiliary connection portion F1 is connected to the connection lead L1 having the opening C, when the ratio of the overlapping area of the orthogonal projection of the auxiliary connection portion F1 on the substrate 01 and the orthogonal projection of the opening C on the substrate 01 to the area of the orthogonal projection of the opening C on the substrate 01 is approximately 50%, the auxiliary connection portion F1 may be connected to the connection lead L1, and patch the connection lead having the opening C, so as to ensure that the connection lead L1 can maintain normal circuit conduction and improve the yield of the connection lead L1.

In addition, since the ratio of the overlapping area of the orthogonal projection of the auxiliary connection portion F1 on the substrate 01 and the orthogonal projection of the opening C on the substrate 01 to the area of the orthogonal projection of the opening C on the substrate 01 is approximately 50%, it may also avoid that the excessive size of the auxiliary connection portion F1 causes the short circuit between the auxiliary connection portion F1 and other adjacent connection lead, and may also save resources.

It will be noted that, due to certain uncontrollable errors (such as manufacturing process errors, equipment accuracy, measurement errors, etc.), in a case where an error of the ratio of the overlapping area of the orthogonal projection of the auxiliary connection portion F1 on the substrate 01 and the orthogonal projection of the opening C on the substrate 01 to the area of the orthogonal projection of the opening C on the substrate 01 fluctuates within a range of 10%×50%, it will also be considered that the ratio of the overlapping area of the orthogonal projection of the auxiliary connection portion F1 on the substrate 01 and the orthogonal projection of the opening C on the substrate 01 to the area of the orthogonal projection of the opening C on the substrate 01 satisfies a condition of being equal to 50%.

In addition, in some other examples, due to certain uncontrollable errors (such as manufacturing process errors, equipment accuracy, measurement errors, etc.), in a case where an error of the ratio of the overlapping area of the orthogonal projection of the auxiliary connection portion F1 on the substrate 01 and the orthogonal projection of the opening C on the substrate 01 to the area of the orthogonal projection of the opening C on the substrate 01 fluctuates within a range of 5%×50%, it will also be considered that the ratio of the overlapping area of the orthogonal projection of the auxiliary connection portion F1 on the substrate 01 and the orthogonal projection of the opening C on the substrate 01 to the area of the orthogonal projection of the opening C on the substrate 01 satisfies a condition of being equal to 50%.

In addition, it will be understood that, due to the limitations of equipment and manufacturing process, the overlapping area of the orthogonal projection of one auxiliary connection portion F1 on the substrate 01 and the orthogonal projection of the opening C on the substrate 01 may not account for 50% of the area of the orthogonal projection of the opening C on the substrate 01; in this case, two, three, or multiple auxiliary connection portions F1 may be arranged in the same opening C, so that a ratio of a sum of overlapping areas of orthogonal projections of multiple auxiliary connection portions F1 on the substrate 01 and the orthogonal projection of the opening C on the substrate 01 to the area of the orthogonal projection of the opening C on the substrate 01 is greater than or equal to 50%.

For example, when the ratio of the overlapping area of the orthogonal projection of one auxiliary connection portion F1 on the substrate 01 and the orthogonal projection of the opening C on the substrate 01 to the area of the orthogonal projection of the opening C on the substrate 01 is approximately 20%, three auxiliary connection portions F1 may be arranged in the same opening, so that a ratio of a sum of overlapping areas of orthogonal projections of the three auxiliary connection portions F1 on the substrate 01 and the orthogonal projection of the opening C on the substrate 01 to the area of the orthogonal projection of the opening C on the substrate 01 is 60%, so as to ensure that the ratio of the sum of overlapping areas of orthogonal projections of multiple auxiliary connection portions F1 on the substrate 01 and the orthogonal projection of the opening C on the substrate 01 to the area of the orthogonal projection of the opening C on the substrate 01 is greater than or equal to 50%. Furthermore, the auxiliary connection portions F1 may be connected to the connection lead L1, and patch the connection lead having the opening C, so as to ensure that the connection lead L1 can maintain normal circuit conduction and improve the yield of the connection lead L1.

It will be noted that when multiple auxiliary connection portions F1 are located in the same opening C, the multiple auxiliary connection portions F1 corresponding to the same opening C may be electrically connected to each other; alternatively, the multiple auxiliary connection portions F1 corresponding to the same opening C may be arranged at intervals. Regardless of which arrangement is adopted, as long as each auxiliary connection portion F1 is ensured to be in the opening C and connected to the connection lead L1 having the opening C, the auxiliary connection portion F1 patches and replaces a part of the opening C formed by the falling off of the connection lead L1, to ensure that the connection lead L1 can maintain normal circuit conduction. The embodiments of the present disclosure are not limited thereto.

In some other embodiments, as shown in FIG. 8, the ratio of the overlapping area of the orthogonal projection of the auxiliary connection portion F1 on the substrate 01 and the orthogonal projection of the opening C on the substrate 01 to the area of the orthogonal projection of the opening C on the substrate 01 is greater than or equal to 80%.

In the case where the auxiliary connection portion F1 is arranged in the opening C and the auxiliary connection portion F1 is connected to the connection lead L1 having the opening C, when the ratio of the overlapping area of the orthogonal projection of the auxiliary connection portion F1 on the substrate 01 and the orthogonal projection of the opening C on the substrate 01 to the area of the orthogonal projection of the opening C on the substrate 01 is equal to or approaches 80%, the auxiliary connection portion F1 may replace more than 80% of the fallen-off part of the connection lead L1, which may patch the connection lead having the opening C better. Therefore, the connection lead L1 may have good electrical performance, which ensures that the connection lead L1 can maintain normal circuit conduction and in turn improves the yield of the connection lead L1.

In some examples, the ratio of the overlapping area of the orthogonal projection of the auxiliary connection portion F1 on the substrate 01 and the orthogonal projection of the opening C on the substrate 01 to the area of the orthogonal projection of the opening C on the substrate 01 is approximately 80%.

In the case where the auxiliary connection portion F1 is arranged in the opening C and the auxiliary connection portion F1 is connected to the connection lead L1 having the opening C, when the ratio of the overlapping area of the orthogonal projection of the auxiliary connection portion F1 on the substrate 01 and the orthogonal projection of the opening C on the substrate 01 to the area of the orthogonal projection of the opening C on the substrate 01 is approximately 80%, the opening C in the connection lead L1 is substantially patched using the auxiliary connection portion, which may ensure that the connection lead L1 can maintain normal circuit conduction and improve the yield of the connection lead L1.

It will be noted that, due to certain uncontrollable errors (such as manufacturing process errors, equipment accuracy, measurement errors, etc.), in a case where an error of the ratio of the overlapping area of the orthogonal projection of the auxiliary connection portion F1 on the substrate 01 and the orthogonal projection of the opening C on the substrate 01 to the area of the orthogonal projection of the opening C on the substrate 01 fluctuates within a range of 10%×80%, it will also be considered that the ratio of the overlapping area of the orthogonal projection of the auxiliary connection portion F1 on the substrate 01 and the orthogonal projection of the opening C on the substrate 01 to the area of the orthogonal projection of the opening C on the substrate 01 satisfies a condition of being equal to 80%.

In addition, in some other examples, due to certain uncontrollable errors (such as manufacturing process errors, equipment accuracy, measurement errors, etc.), in a case where an error of the ratio of the overlapping area of the orthogonal projection of the auxiliary connection portion F1 on the substrate 01 and the orthogonal projection of the opening C on the substrate 01 to the area of the orthogonal projection of the opening C on the substrate 01 fluctuates within a range of 5%×80%, it will also be considered that the ratio of the overlapping area of the orthogonal projection of the auxiliary connection portion F1 on the substrate 01 and the orthogonal projection of the opening C on the substrate 01 to the area of the orthogonal projection of the opening C on the substrate 01 satisfies a condition of being equal to 80%.

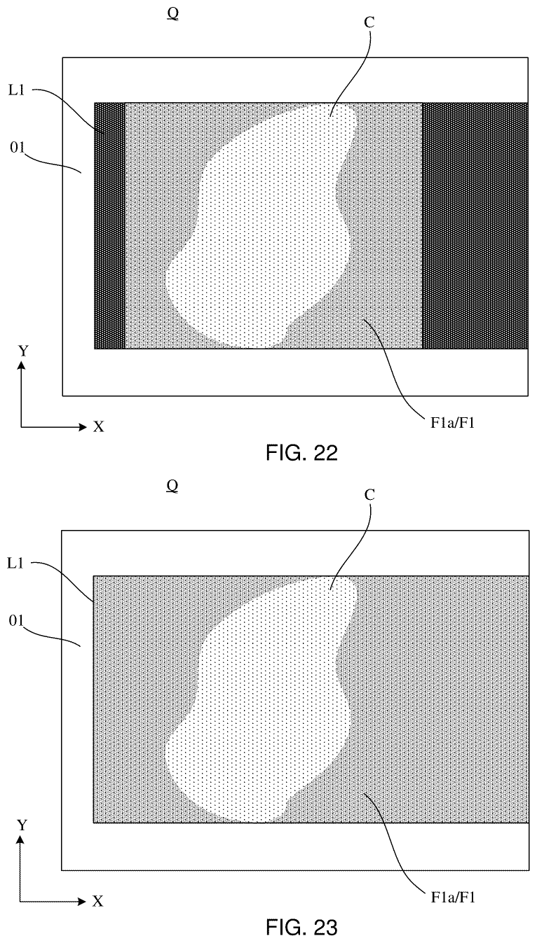

FIG. 22 is a structural diagram of a light-emitting substrate, in accordance with yet some other embodiments.

In yet some other embodiments, as shown in FIG. 22, the ratio of the overlapping area of the orthogonal projection of the auxiliary connection portion F1 on the substrate 01 and the orthogonal projection of the opening C on the substrate 01 to the area of the orthogonal projection of the opening C on the substrate 01 is approximately 100%.

In the case where the auxiliary connection portion F1 is arranged in the opening C and the auxiliary connection portion F1 is connected to the connection lead L1 having the opening C, when the ratio of the overlapping area of the orthogonal projection of the auxiliary connection portion F1 on the substrate 01 and the orthogonal projection of the opening C on the substrate 01 to the area of the orthogonal projection of the opening C on the substrate 01 is equal to or approaches to 100%, the orthogonal projection of the auxiliary connection portion F1 on the substrate 01 covers the orthogonal projection of the opening C on the substrate 01.

The description “the orthogonal projection of the auxiliary connection portion F1 on the substrate 01 covers the orthogonal projection of the opening C on the substrate 01” includes the following two situations.

The first situation is that the orthogonal projection of the auxiliary connection portion F1 on the substrate 01 substantially coincides with the orthogonal projection of the opening C on the substrate 01.

The second situation is that the orthogonal projection of the opening C on the substrate 01 is located within the orthogonal projection of the auxiliary connection portion F1 on the substrate 01.

Regardless of which of the above situations is used, the opening C in the connection lead L1 may be completely filled using the auxiliary connection portion F1, so as to complete the connection lead L1. Based on this, it may be helpful to ensure that the connection lead L1 can maintain normal circuit conduction and improve the yield of the connection lead L1.

It will be noted that, “coincide substantially” includes absolute coincidence and approximate coincidence. That is, a floating range of a gap between a border of the orthogonal projection of the auxiliary connection portion F1 on the substrate 01 and a border of the orthogonal projection of the opening C on the substrate 01 does not exceed an error threshold; and it may also be considered that the auxiliary connection portion F1 and the opening C are relatively “coincident”. The error threshold may be less than 10% of the length of the line segment having the opening C.

FIG. 23 is a structural diagram of a light-emitting substrate, in accordance with yet some other embodiments.

In some embodiments, referring to FIGS. 20 and 23, the orthogonal projection of the auxiliary connection portion F1 on the substrate 01 covers the orthogonal projection of the line segment having the opening C on the substrate 01.

The description “the orthogonal projection of the auxiliary connection portion F1 on the substrate 01 covers the orthogonal projection of the line segment having the opening C on the substrate 01” includes the following two situations.

The first situation is that the orthogonal projection of the auxiliary connection portion F1 on the substrate 01 substantially coincides with the orthogonal projection of the line segment having the opening C on the substrate 01.

The second situation is that the orthogonal projection of the line segment having the opening C on the substrate 01 is located within the orthogonal projection of the auxiliary connection portion F1 on the substrate 01.

In this way, the lapping area of the auxiliary connection portion F1 and the line segment having the opening C may be large, and the auxiliary connection portion F1 may sufficiently patch the line segment having the opening C, so as to ensure that the line segment can maintain normal circuit conduction. In addition, it may also ensure that the auxiliary connection portion F1 is sufficiently in contact with the line segment having the opening C, which is conducive to improving the stability of the connection between the auxiliary connection portion F1 and the connection lead L1.

It will be noted that, “coincide substantially” includes absolute coincidence and approximate coincidence. That is, a floating range of a gap between a border of the orthogonal projection of the auxiliary connection portion F1 on the substrate 01 and a border of the orthogonal projection of the line segment having the opening C on the substrate 01 does not exceed an error threshold; and it may also be considered that edges of the auxiliary connection portion F1 and the line segment are relatively “coincident”. The error threshold may be less than 10% of the length of the line segment having the opening C.

In some embodiments, referring to FIGS. 21 and 23, the orthogonal projection of the auxiliary connection portion F1 on the substrate 01 covers the orthogonal projection of the connection lead L1 having the opening C on the substrate 01.

The description “the orthogonal projection of the auxiliary connection portion F1 on the substrate 01 covers the orthogonal projection of the connection lead L1 having the opening C on the substrate 01” includes the following two situations:

The first situation is that the orthogonal projection of the auxiliary connection portion F1 on the substrate 01 substantially coincides with the orthogonal projection of the connection lead L1 having the opening C on the substrate 01.

The second situation is that the orthogonal projection of the connection lead L1 having the opening C on the substrate 01 is located within the orthogonal projection of the auxiliary connection portion F1 on the substrate 01.

In this way, the lapping area of the auxiliary connection portion F1 and the connection lead L1 having the opening C may be large, and the auxiliary connection portion F1 may sufficiently patch the connection lead L1 having the opening C, so as to ensure that the connection lead L1 can maintain normal circuit conduction. In addition, it may also ensure that the auxiliary connection portion F1 is sufficiently in contact with the connection lead L1 having the opening C, which is conducive to improving the stability of the connection between the auxiliary connection portion F1 and the connection lead L1.

It will be noted that, “coincide substantially” includes absolute coincidence and approximate coincidence. That is, a floating range of a gap between a border of the orthogonal projection of the auxiliary connection portion F1 on the substrate 01 and a border of the orthogonal projection of the connection lead L1 having the opening C on the substrate 01 does not exceed an error threshold; and it may also be considered that the auxiliary connection portion F1 and the connection lead L1 are relatively “coincident”. The error threshold may be less than 10% of the length of the line segment having the opening C.

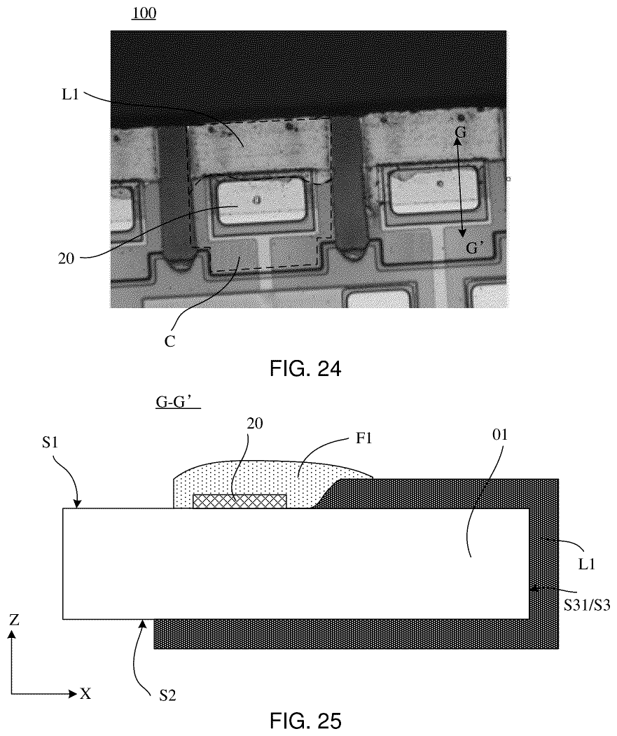

FIG. 24 is a structural diagram of a light-emitting substrate, in accordance with yet some other embodiments. FIG. 25 is a sectional view taken along the line G-G′ in FIG. 24.

In some embodiments, referring to FIGS. 3, 24 and 25, the light-emitting substrate 100 further includes first electrodes 20, and the first electrodes 20 are located on a side of the first main surface S1 away from the second main surface S2.

The first electrode 20 may be electrically connected to the light-emitting chip 10 and a first end of the connection lead L1, so as to realize electrical connection between the connection lead L1 and the light-emitting chip 10. Subsequently, the light-emitting chip 10 is electrically connected to the driver circuit board via the connection lead L1. Therefore, the driving signals provided by the driver circuit board can be transmitted to the light-emitting substrate 100 through the connection leads L1 to control the light-emitting substrate 100 to display images.

In a case where the first end of the connection lead L1 electrically connected to the first electrode 20 includes the opening C, the orthogonal projection of the auxiliary connection portion F1 on the substrate 01 may at least partially overlap with an orthogonal projection of the first electrode 20 on the substrate 01.

Based on this, the auxiliary connection portion F1 may be used to fill the opening C and be connected to the connection lead L1, so as to patch the connection lead L1 to maintain normal circuit conduction. In addition, an area where the auxiliary connection portion F1 overlaps and is in contact with the first electrode 20 may also be used for electrical connection, so as to realize electrical connection between the connection lead L1 and the first electrode 20. This ensures that the driving signals provided by the driver circuit board can be transmitted to the light-emitting substrate 100 through the connection leads L1 to control the light-emitting substrate 100 to display images. As a result, it may be conducive to improving the yield of the light-emitting substrate 100.

In some embodiments, the description “the orthogonal projection of the auxiliary connection portion F1 on the substrate 01 at least partially overlaps with the orthogonal projection of the first electrode 20 on the substrate 01” includes the following two situations.

In the first situation, the orthogonal projection of the auxiliary connection portion F1 on the substrate 01 partially overlaps with the orthogonal projection of the first electrode 20 on the substrate 01.

In the case where the orthogonal projection of the auxiliary connection portion F1 on the substrate 01 overlaps with the orthogonal projection of the first electrode 20 on the substrate 01, the area where the auxiliary connection portion F1 overlaps and is in contact with the first electrode 20 may be used for electrical connection, so as to realize electrical connection between the connection lead L1 and the first electrode 20. This ensures that the driving signals provided by the driver circuit board can be transmitted to the light-emitting substrate 100 through the connection leads L1 to control the light-emitting substrate 100 to display images. As a result, it may be conducive to improving the yield of the light-emitting substrate 100.

In the second situation, the orthogonal projection of the auxiliary connection portion F1 on the substrate 01 covers the orthogonal projection of the first electrode on the substrate 01.

In this way, a lapping area of the auxiliary connection portion F1 and the first electrode 20 may be large, so that the auxiliary connection portion F1 can be electrically connected to the first electrode 20 to realize electrical connection between the connection lead L1 and the first electrode 20. In addition, it may help improve the stability of the connection between the auxiliary connection portion F1 and the first electrode 20, to avoid the disconnection between the connection lead L1 and the first electrode 20 caused by the auxiliary connection portion F1 being detached from the first electrode 20.

The description “the orthogonal projection of the auxiliary connection portion F1 on the substrate 01 covers the orthogonal projection of the first electrode 20 on the substrate 01” may include the following two situations: the orthogonal projection of the auxiliary connection portion F1 on the substrate 01 substantially overlaps with the orthogonal projection of the first electrode on the substrate 01; or the orthogonal projection of the first electrode on the substrate 01 is located within the orthogonal projection of the auxiliary connection portion F1 on the substrate 01. However, the embodiments of the present disclosure are not limited thereto.

In some embodiments, referring to FIGS. 21 and 22, in the case where the orthogonal projection of the auxiliary connection portion F1 on the substrate 01 covers the orthogonal projection of the first electrode 20 on the substrate 01, a first spacing between a border of the orthogonal projection of the auxiliary connection portion F1 on the substrate 01 and a border of the orthogonal projection of the first electrode 20 on the substrate 01 may be less than or equal to 10 μm.

In a case where the first spacing between the border of the orthogonal projection of the auxiliary connection portion F1 on the substrate 01 and the border of the orthogonal projection of the first electrode 20 on the substrate 01 is equal to or approaches 10 μm, it may avoid that a border of the auxiliary connection portion F1 exceeds a border of the first electrode 20 too much, causing short circuit between the auxiliary connection portion F1 and other first electrode 20 adjacent to the corresponding first electrode 20.

In some examples, the first spacing between the border of the orthogonal projection of the auxiliary connection portion F1 on the substrate 01 and the border of the orthogonal projection of the first electrode 20 on the substrate 01 is less than or equal to 5 μm.

In a case where the first spacing between the border of the orthogonal projection of the auxiliary connection portion F1 on the substrate 01 and the border of the orthogonal projection of the first electrode 20 on the substrate 01 is equal to or approaches 5 μm, it may avoid that the border of the auxiliary connection portion F1 exceeds the border of the first electrode 20 too much; in addition, it may reserve overflow space for the auxiliary connection portion F1, and in turn avoid that the excessive size of the auxiliary connection portion F1 causes short circuit between the auxiliary connection portion F1 and other first electrode 20 adjacent to the corresponding first electrode 20.

For example, the first spacing between the border of the orthogonal projection of the auxiliary connection portion F1 on the substrate 01 and the border of the orthogonal projection of the first electrode 20 on the substrate 01 is approximately any one of 3 μm, 5 μm, 8 μm or 10 μm. However, the embodiments of the present disclosure are not limited thereto.

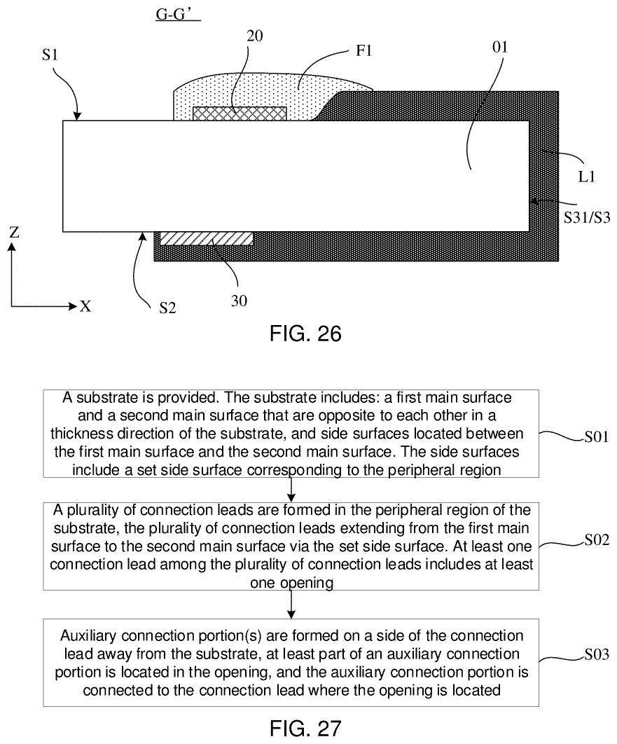

FIG. 26 is another sectional view taken along the line G-G′ in FIG. 24.

In some embodiments, referring to FIGS. 4, 24 and 26, the light-emitting substrate 100 further includes second electrodes 30. The second electrodes 30 are located on a side of the second main surface away from the first main surface S1, and the second electrodes 30 may be electrically connected to the driver circuit board.

The first end of the connection lead L1 is electrically connected to the first electrode 20, and a second end of the connection lead L1 is electrically connected to the second electrode 30. Therefore, the driving signals provided by the driver circuit board can be transmitted to the light-emitting substrate 100 through the connection leads L1 to control the light-emitting substrate 100 to display images.

In a case where the second end of the connection lead L1 electrically connected to the second electrode 30 includes the opening C, the orthogonal projection of the auxiliary connection portion F1 on the substrate 01 may at least partially overlap with an orthogonal projection of the second electrode 30 on the substrate 01.

Based on this, the auxiliary connection portion F1 may be used to fill the opening C and be connected to the connection lead L1, so as to patch the connection lead L1 to maintain normal circuit conduction. In addition, an area where the auxiliary connection portion F1 overlaps and is in contact with the second electrode 30 may also be used for electrical connection, so as to realize electrical connection between the connection lead L1 and the second electrode 30. This ensures that the driving signals provided by the driver circuit board can be transmitted to the light-emitting substrate 100 through the connection leads L1 to control the light-emitting substrate 100 to display images. As a result, it may be conducive to improving the yield of the light-emitting substrate 100.

In some embodiments, the description “the orthogonal projection of the auxiliary connection portion F1 on the substrate 01 at least partially overlaps with the orthogonal projection of the second electrode 30 on the substrate 01” includes the following two situations.

In the first situation, the orthogonal projection of the auxiliary connection portion F1 on the substrate 01 partially overlaps with the orthogonal projection of the second electrode 30 on the substrate 01.

In the case where the orthogonal projection of the auxiliary connection portion F1 on the substrate 01 overlaps with the orthogonal projection of the second electrode 30 on the substrate 01, the area where the auxiliary connection portion F1 overlaps and is in contact with the second electrode 30 may also be used for electrical connection, so as to realize electrical connection between the connection lead L1 and the second electrode 30. This ensures that the driving signals provided by the driver circuit board can be transmitted to the light-emitting substrate 100 through the connection leads L1 to control the light-emitting substrate 100 to display images. As a result, it may be conducive to improving the yield of the light-emitting substrate 100.

In the second situation, the orthogonal projection of the auxiliary connection portion F1 on the substrate 01 covers the orthogonal projection of the second electrode on the substrate 01.

In this way, a lapping area between the auxiliary connection portion F1 and the second electrode 30 may be large, so that the auxiliary connection portion F1 can be electrically connected to the second electrode 30 to realize electrical connection between the connection lead L1 and the second electrode 30. In addition, it may help improve the stability of the connection between the auxiliary connection portion F1 and the second electrode 30, to avoid the disconnection between the connection lead L1 and the second electrode 30 caused by the auxiliary connection portion F1 being detached from the second electrode 30.

The description “the orthogonal projection of the auxiliary connection portion F1 on the substrate 01 covers the orthogonal projection of the second electrode 30 on the substrate 01” may include the following two situations: the orthogonal projection of the auxiliary connection portion F1 on the substrate 01 substantially overlaps with the orthogonal projection of the second electrode on the substrate 01; or the orthogonal projection of the second electrode on the substrate 01 is located within the orthogonal projection of the auxiliary connection portion F1 on the substrate 01. However, the embodiments of the present disclosure are not limited thereto.

In some embodiments, the light-emitting substrate 100 may further include a protective layer. The protective layer is made of an insulating material. The protective layer covers the connection leads L1 and auxiliary connection portions F1 corresponding to the connection leads L1. The protective layer has a certain viscosity. Therefore, the protective layer may be used to assist in reinforcing the auxiliary connection portion F1 and the connection lead L1, which improves the stability of the connection lead L1 in the light-emitting substrate 100 and avoids the detachment problem of the connection lead L1 and the auxiliary connection portion F1. A thickness of the protective layer is greater than a sum of the thickness of the connection lead L1 and the thickness of the auxiliary connection portion F1, and a surface of the protective layer is flat at each position. As a result, it is conducive to improving the yield of the light-emitting substrate 100.

In some examples, the protective layer may be made of at least one of an optically clear adhesive or fluorinating agent. However, the embodiments of the present disclosure are not limited thereto.

In addition, in the above embodiments, the opening(s) are formed by bumps, scratches or natural falling off of the connection lead L1, and are not intentionally made by human. For example, a region where the connection lead L1 is located may have opening(s) in approximately 10% or less of the region. Based on this, the auxiliary connection portion F1 is provided in the light-emitting substrate 100 to patch the detached connection lead L1. However, the present disclosure is not limited thereto. It can be understood that, in some other embodiments, after the connection lead L1 is formed, it is considered that an opening C is formed in the connection lead L1; and at least part of an auxiliary connection portion F1 is located in the opening C, and the auxiliary connection portion F1 is electrically connected to the connection lead L1. Based on this, the auxiliary connection portion F1 may be used to replace the structure of the opening of the connection lead L1. Furthermore, based on the above structure, the auxiliary connection portion F1 may be used to adjust the resistance and other characteristics of the connection lead L1.

In summary, the opening in the connection lead L1 in the embodiments of the present disclosure may be formed in the following two manners. The first manner is non-human operation, and the opening is formed by natural falling off of the connection lead L1. For example, a shape of the opening C is generally irregular. However, the shape of the opening C is not limited thereto, which may be a regular shape, such as square, circle, triangle, etc. The second manner is human operation, and the opening C is formed in the connection lead L1 by cutting, etching or other ways. For example, the shape of the opening C is generally a regular shape, such as square, circle, triangle, etc. However, the shape of the opening C is not limited thereto, which may be an irregular shape.

FIG. 27 is a flow diagram of a method for manufacturing a light-emitting substrate, in accordance with some embodiments.

Referring to FIG. 27, some embodiments of the present disclosure provide a method for manufacturing a light-emitting substrate 100, and the method is used for manufacturing the light-emitting substrate 100 as described in any of the above embodiments. The light-emitting substrate 100 includes a display region and a peripheral region located on at least one side of the display region. As shown in FIG. 3, the light-emitting substrate 100 includes a display region (also referred to as an active area (AA region for short), or an active display region) AA and a peripheral region SA. The peripheral region SA is located on at least one side (e.g., one side; or four sides, including upper and lower sides and left and right sides) of the display region AA.

The method includes the following steps.

In S01, a substrate is provided. The substrate includes: a first main surface and a second main surface that are opposite to each other in a thickness direction of the substrate, and side surface(s) located between the first main surface and the second main surface. The side surface(s) include a set side surface corresponding to the peripheral region.

In S02, a plurality of connection leads are formed in the peripheral region of the substrate, the plurality of connection leads extending from the first main surface to the second main surface via the set side surface. At least one connection lead among the plurality of connection leads includes at least one opening.

During step S02, referring to FIG. 5, after the plurality of connection leads L1 are formed in the peripheral region SA of the substrate 01, an open circuit test is performed on the light-emitting substrate 100, and at least part of the plurality of connection leads L1 in the light-emitting substrate 100 has a disconnection problem.

The inventors have found through research that the main reason for the low yield of the connection leads L1 is that the existing manufacturing process cannot meet the environmental cleanliness requirement of the connection leads L1, which will cause a part of the connection lead L1 to fall off to form an opening C, and the opening C affects the yield of the connection leads L1.

For example, the connection leads L1 may fall off in spots, at edges, or over large areas, and the above-mentioned falling off situations will result in openings C of different shapes and sizes in the connection leads L1. Regardless of the types of the openings C, the quality of the connection leads L1 will be reduced, and the yield of the connection leads L1 will also be reduced.

In view of the above problems, the method for manufacturing the light-emitting substrate 100 provided in the embodiments of the present disclosure further includes the following step.

In S03, referring to FIGS. 6 and 7, auxiliary connection portion(s) are formed on a side of the connection lead away from the substrate, at least part of the auxiliary connection portion is located in the opening, and the auxiliary connection portion is connected to the connection lead where the opening is located.

During step S03, referring to FIGS. 8 and 9, when an opening C formed in the connection lead L1 is found after the open circuit test, an auxiliary connection portion F1 will be formed at the position of the opening C so that at least part of the auxiliary connection portion F1 is arranged in the opening C, and the auxiliary connection portion F1 is used to be connected to the connection lead L1 where the opening C is located.

Based on this, the auxiliary connection portion F1 may patch the opening C formed by the falling off of the connection lead L1. That is, the auxiliary connection portion F1 may replace the fallen-off part of the connection lead L1, so that the connection lead L1 can maintain normal circuit conduction. Therefore, the yield of the connection leads L1 may be improved.

In some examples, one auxiliary connection portion F1 may patch one opening C. In some other examples, multiple auxiliary connection portions F1 may patch one opening C. For example, the multiple auxiliary connection portions F1 are arranged in a length direction of the opening C, so that the multiple auxiliary connection portions F1 are all arranged in the opening C. In yet some other examples, one auxiliary connection portion F1 may patch a plurality of adjacent openings C. For example, when the connection lead L1 has a plurality of openings C arranged in a certain direction, one auxiliary connection portion F1 extending in the certain direction may be provided, so that the auxiliary connection portion F1 fills the plurality of openings C. However, the embodiments of the present disclosure are not limited thereto. The following description will be made by taking one auxiliary connection portion F1 patching one opening C as an example.

In summary, the embodiments of the present disclosure provide a method for manufacturing a light-emitting substrate 100, when an opening C formed in the connection lead L1 is found, an auxiliary connection portion F1 may be formed at a position corresponding to the opening C, so that at least part of the auxiliary connection portion F1 is disposed in the opening C, and the auxiliary connection portion F1 is used to be connected to the connection lead L1 where the opening C is located. Thus, the auxiliary connection portion F1 may replace the fallen-off part of the connection lead L1, and the connection lead L1 can maintain normal circuit conduction. As a result, the yield of the connection leads L1 may be improved.

In some embodiments, referring to FIGS. 5 and 23, step S02 in which the plurality of connection leads are formed in the peripheral region of the substrate may include: forming the plurality of connection leads on the substrate through a sputtering process (PVD Sputter).

In some examples, this step may include:
forming a protective layer on the substrate 01, the protective layer covering the display region AA and exposing the peripheral region SA;
forming a metal layer in the peripheral region SA exposed by the protective layer through the sputtering process (PVD Sputter); and patterning the metal layer to form the plurality of connection leads L1.

For example, the metal layer may undergo laser etching to form the plurality of connection leads L1.

In some other examples, this step may include:
providing a mask, the mask including openings, where the openings of the mask correspond to shapes of the plurality of connection leads; and
forming the plurality of connection leads L1 on the substrate 01 through the sputtering process (PVD Sputter) using the mask.

Regardless of which of the above-mentioned methods for forming the connection leads L1 is used, it is all formed by using a sputtering process (PVD Sputter). The inventors have found through research that the sputtering process (PVD Sputter) has a high requirement for the cleanliness of its working environment in order to ensure the adhesion of the formed metal layer. However, the existing work cannot meet the requirement of the sputtering process (PVD Sputter) for environmental cleanliness. As a result, the connection leads L1 formed by the sputtering process (PVD Sputter) are prone to partial detachment, which affects the yield of the connection leads L1.

Based on this, step S03 in which the auxiliary connection portion is formed on the side of the connection lead away from the substrate may include: forming the auxiliary connection portion on the side of the connection lead away from the substrate through a three-dimensional printing process, so that at least part of the auxiliary connection portion F1 is disposed in the opening C, and the auxiliary connection portion F1 is connected to the connection lead L1 where the opening C is located.

Based on this, the auxiliary connection portion F1 may patch the opening C formed by the falling off of the connection lead L1. That is, the auxiliary connection portion F1 may replace the fallen-off part of the connection lead L1, so that the connection lead L1 can maintain normal circuit conduction. Therefore, the yield of the connection leads L1 may be improved. Furthermore, by using the three-dimensional printing process to form the auxiliary connection portion F1, the auxiliary connection portion F1 may be accurately formed at the position of the opening C of the connection lead L1, thereby improving the accuracy of positioning the auxiliary connection portion F1.

However, the embodiments of the present disclosure are not limited thereto, and other processes that can realize specified patching may also be adopted.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure should be determined by the protection scope of the claims.

1. A light-emitting substrate, comprising a display region and a peripheral region located on at least one side of the display region; the light-emitting substrate further comprising:
a substrate including: a first main surface and a second main surface that are opposite to each other in a thickness direction of the substrate, and side surfaces between the first main surface and the second main surface, wherein the side surfaces include a set side surface corresponding to the peripheral region;
a plurality of connection leads located on the substrate and extending from the first main surface to the second main surface via the set side surface, wherein the plurality of connection leads are located in the peripheral region, and connection lead of at least one connection lead among the plurality of connection leads includes at least one opening; and
at least one auxiliary connection portion wherein at least part of an auxiliary connection portion of the at least one auxiliary connection portion is located in the opening, and the auxiliary connection portion is connected to the connection lead where the opening is located.

2. The light-emitting substrate according to claim 1, wherein the auxiliary connection portion is located in the opening, and the auxiliary connection portion abuts against an edge of the connection lead that forms the opening.

3. The light-emitting substrate according to claim 1, wherein the auxiliary connection portion includes a main body portion and at least one lapping portion connected to the main body portion;
the main body portion is located in the opening, the lapping portion is located on a side of the connection lead away from the substrate, and the lapping portion is in contact with the side of the connection lead away from the substrate.

4. The light-emitting substrate according to claim 3, wherein in a direction pointing from the main body portion to the lapping portion, a width of the lapping portion is greater than or equal to 10 μm.

5. The light-emitting substrate according to claim 1, wherein the connection lead includes three line segments connected in sequence; at least one line segment of the three line segments of the connection lead includes the at least one opening; the three line segments are a first line segment located on the first main surface, a third line segment located on the set side surface, and a second line segment located on the second main surface;
the auxiliary connection portion is located on a line segment having an opening; and in an extending direction of the line segment having the opening, a length of the auxiliary connection portion is less than or equal to a length of the line segment having the opening.

6. The light-emitting substrate according to claim 1, wherein in an extending direction of the connection lead having the opening, a length of the auxiliary connection portion is less than or equal to a length of the connection lead having the opening.

7. The light-emitting substrate according to claim 1, wherein in a width direction of the connection lead, a ratio of a width of the at least part of the auxiliary connection portion located in the opening to a width of the opening is greater than or equal to 50%.

8. The light-emitting substrate according to claim 1, wherein a width of the auxiliary connection portion is in a range of 50 μm to 100 μm.

9. The light-emitting substrate according to claim 1, wherein a ratio of an overlapping area of an orthogonal projection of the auxiliary connection portion on the substrate and an orthogonal projection of the opening on the substrate to an area of the orthogonal projection of the opening on the substrate is greater than or equal to 50%.

10. The light-emitting substrate according to claim 1, wherein a ratio of an overlapping area of an orthogonal projection of the auxiliary connection portion on the substrate and an orthogonal projection of the connection lead having the opening on the substrate to an area of an orthogonal projection of the opening on the substrate is greater than or equal to 80%.

11. The light-emitting substrate according to claim 1, wherein the at least one auxiliary connection portion includes at least two portions, and the at least two auxiliary connection portions are at least partially located in a same opening.

12. The light-emitting substrate according to claim 1, further comprising first electrodes located on a side of the first main surface away from the second main surface, wherein
a first end of the connection lead is electrically connected to a first electrode, the first end includes an opening, and an orthogonal projection of the auxiliary connection portion on the substrate covers an orthogonal projection of the first electrode on the substrate.

13. The light-emitting substrate according to claim 12, wherein a first spacing between a border of the orthogonal projection of the auxiliary connection portion on the substrate and a border of the orthogonal projection of the first electrode on the substrate is less than or equal to 5 μm.

14. The light-emitting substrate according to claim 1, wherein a sheet resistance of the auxiliary connection portion is less than or equal to a sheet resistance of the connection lead.

15. The light-emitting substrate according to claim 1, wherein a thickness of the auxiliary connection portion is in a range of 5 μm to 20 μm.

16. The light-emitting substrate according to claim 1, wherein a material of the auxiliary connection portion includes a conductive adhesive.

17. The light-emitting substrate according to claim 1, wherein a material of the connection lead includes metal.

18. A method for manufacturing a light-emitting substrate, the light-emitting substrate including a display region and a peripheral region located on at least one side of the display region, the method comprising:
providing a substrate, the substrate including: a first main surface and a second main surface that are opposite to each other in a thickness direction of the substrate, and side surfaces between the first main surface and the second main surface, wherein the side surfaces include a set side surface corresponding to the peripheral region;
forming a plurality of connection leads in the peripheral region of the substrate, the plurality of connection leads extending from the first main surface to the second main surface via the set side surface, wherein each connection lead of at least one connection lead among the plurality of connection leads includes at least one opening; and
forming at least one auxiliary connection portion on a side of the at least one connection lead away from the substrate, wherein at least part of an auxiliary connection portion of d set one auxiliary connection portion is located in the opening, and the auxiliary connection portion is connected to the connection lead where the opening is located.

19. The method according to claim 18, wherein
forming the plurality of connection leads in the peripheral region of the substrate includes:
forming the plurality of connection leads on the substrate through a sputtering process; and
forming the at least one auxiliary connection portion on the side of the at least one connection lead away from the substrate includes:
forming the at least one auxiliary connection portion on the side of the at least one connection lead away from the substrate through a three-dimensional printing process, so that the at least part of the auxiliary connection portion is located in the opening, and the auxiliary connection portion is connected to the connection lead where the opening is located.

20. A display apparatus, comprising the light-emitting substrate according to claim 1.
